(19) United States
(12) Patent Application Publication
(10) Pub. No.: US 2026/0361350 A1
(43) Pub. Date: Nov. 12, 2026

(54) Systems and Methods for Low Bit-Width Numerics

(71) Applicant: Cerebras Systems Inc., Sunnyvale, CA (US)

(72) Inventor: Valavan Manohararajah, Sunnyvale, CA (US)

(21) Appl. No.: 19/648,857

(22) Filed: Apr. 15, 2026

Related U.S. Application Data
(60) Provisional application No. 63/789,775, filed on Apr. 16, 2025.

(51) Int. Cl. H04B 7/0456

(52) U.S. Cl. CPC H04B 7/0456

(57) ABSTRACT

The present disclosure includes systems and methods for representing numerical quantities for more efficient storage, transmission, and manipulation in computer hardware. A method includes generating a codebook and optimizing the codebook. The codebook is optimized based on reducing one or more of a data reconstruction error of a target distribution or a complexity of one or more associated logic functions. The logic functions are used for decoding and encoding one or more values based on the codebook.

### CROSS-REFERENCE TO RELATED APPLICATIONS

The present application claims priority to and the benefit of U.S. Provisional Patent Application No. 63/789,775, filed in the U.S. Patent and Trademark Office on Apr. 16, 2025, which is hereby incorporated by reference in its entirety.

### TECHNICAL FIELD

The present disclosure relates to representation of numerical quantities (e.g., for storage, transmission, and manipulation in computer hardware).

### SUMMARY

Many software applications such as computational modeling and artificial intelligence (AI) agents rely on large datasets and high-precision numerics. For example, rather than storing weights of a neural network directly into memory, indices may instead be stored into memory, occupying fewer bits than for a value of higher precision, and used to point to entries that approximate a given weight. Storing and transferring large numerical datasets using compact data representations may be beneficial because compact data representations reduce memory and bandwidth usage. Large datasets, however, may present challenges in terms of how data may be compactly represented and how computational precision may be preserved in hardware. For example, depending on how data is stored and encoded, certain approaches may result in difficulties in managing data, increased computational latency, and memory-intensive applications.

In some approaches, to provide compact data representations, values of a data set may be individually encoded. Doing so, however, may cause allocation of a substantial number of bits to an exponent field. That is, some compact floating-point formats may be inefficient in terms of the representational value provided by a fixed number of bits (e.g., depending on how well an encoding scheme captures elements of a distribution of data). Moreover, in some approaches, handling outliers, or any suitable values that have magnitudes significantly greater than most of a dataset, may be handled differently from the majority of a dataset, thereby resulting in additional performance overhead.

In some approaches, handling encoded values or large high-precision datasets may result in inefficiencies depending on storage methods. For example, storing encoded values in memory that is distant from processing circuitry (e.g., external memory) may incur extraneous area, power, and performance overhead. In addition, in some approaches, encoding may incur a search through one or more codebooks during a pre-processing step before the main computations for an inference task (e.g., to avoid adding overhead). In such approaches, however, codebooks may not be usable real-time for values generated as part of the main computations.

Accordingly, some embodiments disclosed herein provide ways to realize compact representations of numerical quantities for more efficient storage, transmission, and manipulation. For example, in some embodiments, codebooks may be selected based on respective numerical distributions. In some embodiments, data may be encoded in a blocked format that accounts for complexities resulting from handling outlier values. In some embodiments, low complexity encoding and decoding functions may be determined to realize mappings provided by one or more codebooks.

In some embodiments, a method for performing a coding operation is provided. The method may include the following steps in any suitable order: determining a mapping between a first plurality of values and a code to perform a quantization operation; determining a logic function based on the mapping and the coding operation; selecting a codebook from a plurality of codebooks to perform the coding operation on a second plurality of values, wherein the selected codebook is based on the first plurality of values, and the second plurality of values and the first plurality of values share a characteristic; and performing the coding operation on the second plurality of values using the logic function based on the codebook.

In some embodiments, a quantization operation includes a forward quantization operation, and a coding operation includes an encoding operation.

In some embodiments, the method may include rounding a second plurality of values and using a rounded plurality of values as input into a logic function.

In some embodiments, the method may include saturating a second plurality of values based on a maximum representable value and using a saturated second plurality of values as input into a logic function.

In some embodiments, a quantization operation includes a de-quantization operation and a coding operation includes a decoding operation.

In some embodiments, mapping a first plurality of values to a code includes determining a reconstruction error from converting the first plurality of values between a native representation and a code.

In some embodiments, determining a logic function based on a mapping and a coding operation includes reducing a complexity metric associated with performing the coding operation using the logic function, and a complexity metric is indicative of a number of operations of a logic function.

In some embodiments, a characteristic includes at least one of: a maximum exponent, a distribution metric, or a statistic.

In some embodiments, each of a plurality of codebooks is tuned based on a respective numerical distribution.

In some embodiments, the method may include determining an outlier of a second plurality of values; and determining each of a second plurality of values as a respective offset based on the outlier, where a respective offset of an outlier is encoded as a center of the second plurality of values.

### BRIEF DESCRIPTION OF THE DRAWINGS

FIG. 1 depicts an example illustration of a codebook having a number of entries that define a mapping from a code to one or more values, in accordance with one or more embodiments of the present disclosure;

FIG. 2 depicts an example decoding unit that decodes a code into one or more values, and an example encoding unit that encodes one or more values into a code based on a codebook, in accordance with one or more embodiments of the present disclosure;

FIG. 3 illustrates an example scenario including selecting one or more codebooks used for decoding and encoding, in accordance with one or more embodiments of the present disclosure;

FIG. 4 illustrates an example system to select a codebook, in accordance with one or more embodiments of the present disclosure;

FIG. 5 is an example flowchart of a heuristic optimization algorithm to generate a codebook, in accordance with one or more embodiments of the present disclosure;

FIG. 6 illustrates an example of a blocked numeric format that preserves outlier values, in accordance with one or more embodiments of the present disclosure;

FIG. 7 depicts an example system to encode values into an outlier preserving blocked format, in accordance with one or more embodiments of the present disclosure;

FIG. 8 depicts an example system to decode an outlier preserving blocked format into numerical values, in accordance with one or more embodiments of the present disclosure;

FIG. 9 depicts an example system to construct an outlier preserving blocked format based on a codebook, in accordance with one or more embodiments of the present disclosure;

FIG. 10 depicts an example system to recover values from an outlier preserving blocked format based on a codebook, in accordance with one or more embodiments of the present disclosure;

FIG. 11 depicts an example compute acceleration unit that uses blocked formats for its input and output, in accordance with one or more embodiments of the present disclosure;

FIG. 12 depicts an example compute acceleration unit with an attached local memory store that uses blocked formats for its input and output, in accordance with one or more embodiments of the present disclosure;

FIG. 13 shows a block diagram illustrating an example compute accelerator, such as a deep learning accelerator (DLA), in accordance with one or more embodiments of the present disclosure;

FIGS. 14A-14C shows block diagrams illustrating some example configurations of a compute accelerator, in accordance with one or more embodiments of the present disclosure;

FIG. 15 shows a block diagram illustrating an example processing element (PE) of a compute accelerator, in accordance with one or more embodiments of the present disclosure; and

FIG. 16 is a flowchart of an example process for performing a coding operation, in accordance with one or more embodiments of the present disclosure.

### DETAILED DESCRIPTION

In some embodiments, source numerical data is provided in a floating-point format with bits designated for sign, power-of-2 exponent, and mantissa (e.g., as may be used in scientific and neural network applications). It is noted that the embodiments described in the present disclosure are not limited to such representations, and the embodiments can be readily adapted for source data in an integer format such as two's complement or sign-magnitude.

Some embodiments of the present disclosure may include configurations for prioritizing efficient hardware implementations. For example, both decoding and encoding steps may be implemented in hardware. For example, a first portion of circuitry may be configured for decoding (e.g., as a decoding unit), and a second portion of circuitry may be configured for encoding (e.g., as an encoding unit). Some embodiments of the present disclosure related to encoding and associated processes can be implemented in software. In some embodiments, the complexity of encoding may be considered during optimization objectives.

In some embodiments, codebook-based encoding processes provide a compact and high integrity representation of numerical data. It will be understood that references to compact data representations herein may refer to data representations that are more compact with respect to an unencoded counterpart. For example, encoded data may be more compact than unencoded data representing the same information as the encoded data. Furthermore, difference schemes may result in some versions of encoded data that are more compact than other representations of encoded data. For example, a first version of encoded data may be more compact than a second version of encoded data if the first version occupies less storage space than the second version while representing the same information.

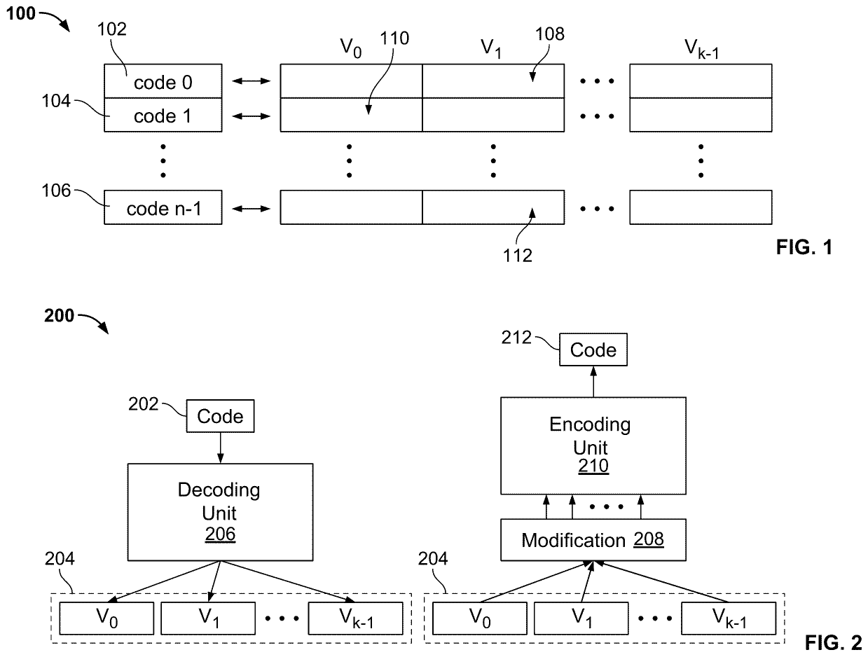

FIG. 1 depicts an example illustration of a codebook (e.g., codebook 100) having a number of entries that define a mapping from a code to one or more values, in accordance with one or more embodiments of the present disclosure. In some embodiments, codebook 100 may include one or more look up tables that map indices to one or more values that are of a higher precision than the indices. In some embodiments, codebook 100 may include mappings to codes 102, 104, and 106. In some embodiments, a code (e.g., codes 102, 104, and 106) may be any suitable identifier that is indicative of an entry in a codebook. For example, a code may be used to determine a centroid, codeword, or any other suitable value used to reconstruct an approximation of an original weight.

While codes 102, 104, and 106 are illustrated in FIG. 1, it will be understood that any suitable number of codes may be represented while still being in accordance with some embodiments disclosed herein. In some embodiments, each respective code may map to one or more values. For example, code 102 may map to one or more values 108, code 104 may map to one or more values 110, and code 106 may map to one or more values 112. It will be understood that mappings between codes and one or more values may be bi-directional.

In some embodiments, a code may be replaced by the values to which it maps. Based on the values, a search may be performed through the codebook to find a particular codebook entry (e.g., the closest matching codebook entry) and use its corresponding code as the representation of the values. In some embodiments, a matching codebook entry may be a codebook that minimizes the squared error between the original values and the codebook entry.

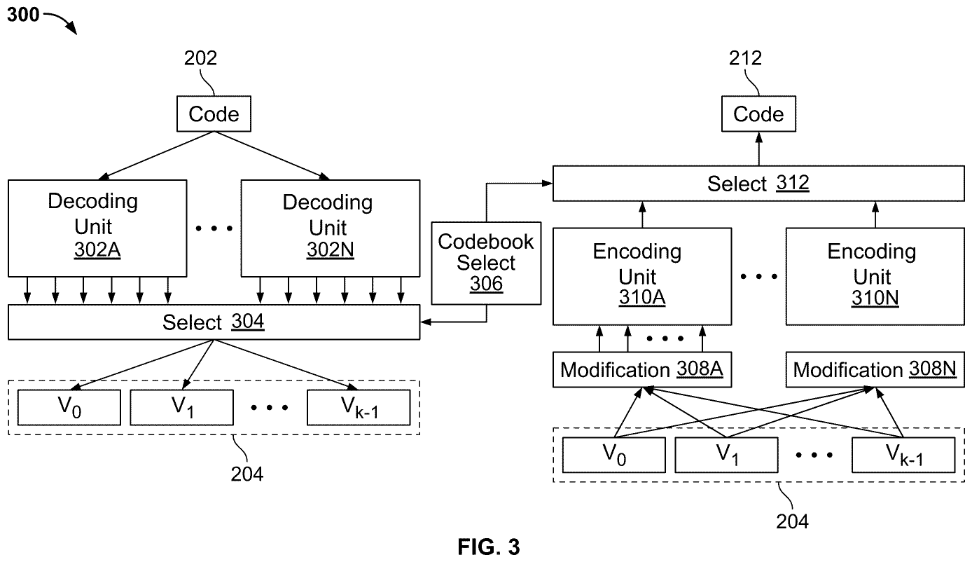

In some embodiments, one or more processors may utilize one or more logic circuits (e.g., circuitry) for encoding and decoding data, as further described below (e.g., in connection with FIG. 2). FIG. 2 depicts an example decoding unit that decodes a code into one or more values, and an example encoding unit that encodes one or more values into a code based on a codebook, in accordance with one or more embodiments of the present disclosure.

In some embodiments, circuitry (e.g., decoding unit 206) may be configured to decode code 202 into at least one value of one or more values 204. It will be understood that decoding unit 206 and associated circuitry may be implemented by one or more suitable hardware units (e.g., any suitable processing circuitry described herein). For example, decoding unit 206 may utilize one or more logic gates or other suitable circuit elements to decode code 202 to one or more values 204. In some embodiments, circuitry (e.g., encoding unit 210) may be configured to encode a value into a code. It will be understood that encoding unit 210 may be implemented by one or more suitable hardware units (e.g., any suitable processing circuitry described herein). For example, encoding unit 210 may utilize one or more logic gates or other circuit elements to encode one or more values 204 into code 212. Furthermore, in some embodiments, code 202 may be the same as code 212. In some embodiments, however, code 202 may be different from code 212.

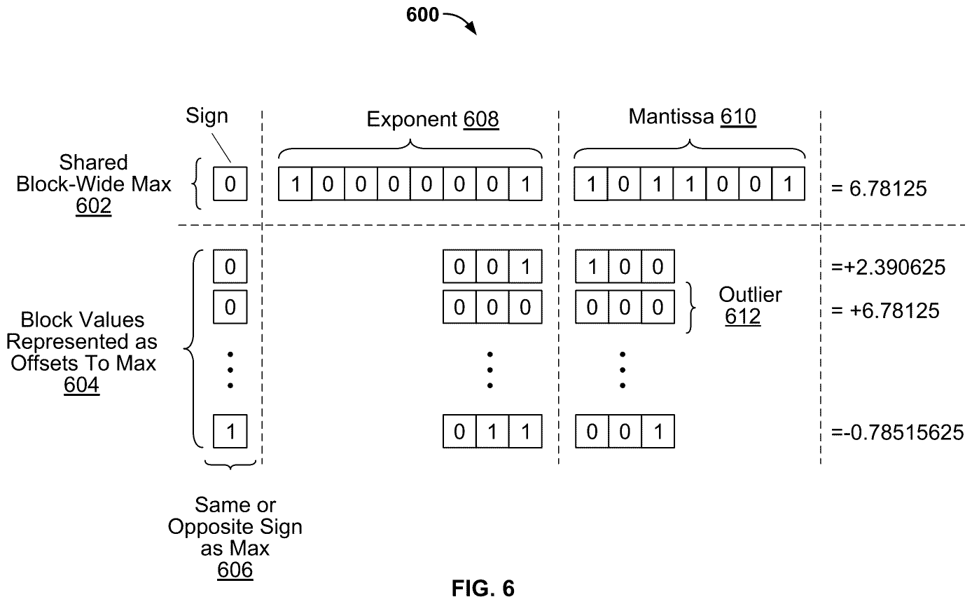

In some embodiments, circuitry may be configured to determine an optimal mapping for converting between code 202 and one or more values 204 and for converting between one or more values 204 and code 212. For example, circuitry may determine a mapping that reduces (e.g., minimizes) error between conversions. An example process to determine a mapping between a code and one or more values is described below (e.g., in connection with FIG. 5).

In some embodiments, decoding data includes converting code 202 into one or more values 204 using decoding unit 206. In some embodiments, decoding unit 206 may implement one or more functions that operate on binary inputs and produce binary outputs based on one or more rules. In some embodiments, decoding unit 206 may realize any suitable truth table, Boolean logic, any other type of information that may be used to operate electronic components, or combinations thereof. For example, decoding unit 206 may implement a function describing how to operate one or more logic gates to perform a task, such as decoding code 202 into one or more values 204.

In some embodiments, one or more values 204 may be encoded as code 212. For example, in some embodiments, one or more values 204 may undergo modification 208.

Modification 208 may include rounding, saturating, truncating, trimming, clipping, any suitable operation used to convert more precise data into less precise data, or combinations thereof. For example, modification 208 may be applied to BF16 values, which normally have 65,536 possible values. In some embodiments, complexity of a BF16 value may be reduced using modification 208 by trimming a value to a 10-bit representation (e.g., 1 sign bit, 4 exponent bits and 5 mantissa bits), leaving only 1024 possibilities. Modification 208 may be implemented by rounding off the 2 least significant mantissa bits and applying saturation, which limits any value exceeding the maximum representable 10-bit value at that maximum limit.

In some embodiments, encoding unit 210 may be used to encode at least one value of one or more values 204 into code 212. Encoding unit 210 may include at least some of the same properties of decoding unit 206 (e.g., encoding unit 210 may implement any suitable type of function that may be used to operate electronic components). In some embodiments, encoding unit 210 may operate on data modified by modification 208 or directly operate on one or more values 204.

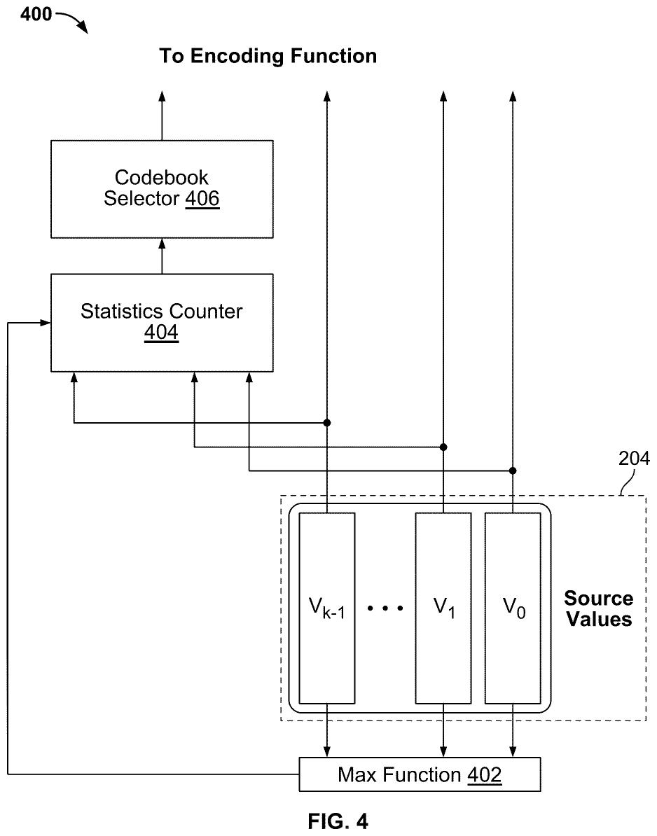

In some embodiments, a plurality of codebooks may be used for encoding and decoding. In some embodiments, multiple codebooks may be used where each is tuned to a different numerical distribution and compression goal. FIG. 3 illustrates an example scenario including selecting one or more codebooks used for decoding and encoding, in accordance with one or more embodiments of the present disclosure. In some embodiments, diagram 300 illustrates code 202 being decoded into one or more values 204 and one or more values 204 being encoded into code 212.

In some embodiments, codebooks may be tuned for different distributions. In some embodiments, some or all codebooks may differ in number of values decoded and encoded simultaneously. In some embodiments, any suitable number of codebooks may be employed. For example, a first codebook may utilize decoding unit 302A that maps one value to a 6-bit code, and a second codebook may utilize decoding unit 302N that maps a pair of values to a 6-bit code. A first codebook using decoding unit 302A may achieve different compression and accuracy trade-offs with respect to decoding unit 302N. It will be understood that any suitable number of codebooks may be used with any suitable respective number of decoding units to perform decoding, and two different decoding units are shown merely for the sake of example.

In some embodiments, at 304, a set of results generated by a respective codebook may be selected based on signal 306. Signal 306 may be any suitable signal used to determine which results of a respective codebook to use. For example, signal 306 may be a codebook selection signal indicating to use results from a first codebook that utilizes decoding unit 302A. In some embodiments, signal 306 may be provided by a configuration register. In some embodiments, signal 306 is shared by a block of values and provided by bits packed into the block. In some embodiments, signal 306 may be determined during encoding by observing one or more statistics of a block of values being encoded.

In some embodiments, one or more values 204 may be decoded. At least one value of one or more values 204 may undergo modifications 308A-308N. While only two modifications are shown, it will be understood that any suitable number of modifications may occur (e.g., based on a number of codebooks). Furthermore, any of modifications 308A-308N may correspond to modification 208. For example, modification 308A may include a rounding and saturation modification.

Furthermore, results of a respective modification may be used as input for a respective encoding unit. For example, results of modification 308A may be used as input for encoding unit 310A, and results of modification 308N may be used as input for encoding unit 310N. While only two encoding units are shown, it will be understood that any suitable number of encoding units may be used (e.g., based on a number of codebooks). Furthermore, any of encoding units 310A-310N may correspond to encoding unit 210.

In some embodiments, at 312, results of a codebook may be selected to determine how to generate code based on at least one value of one or more values 204. In some embodiments, signal 306 may be used to perform 312.

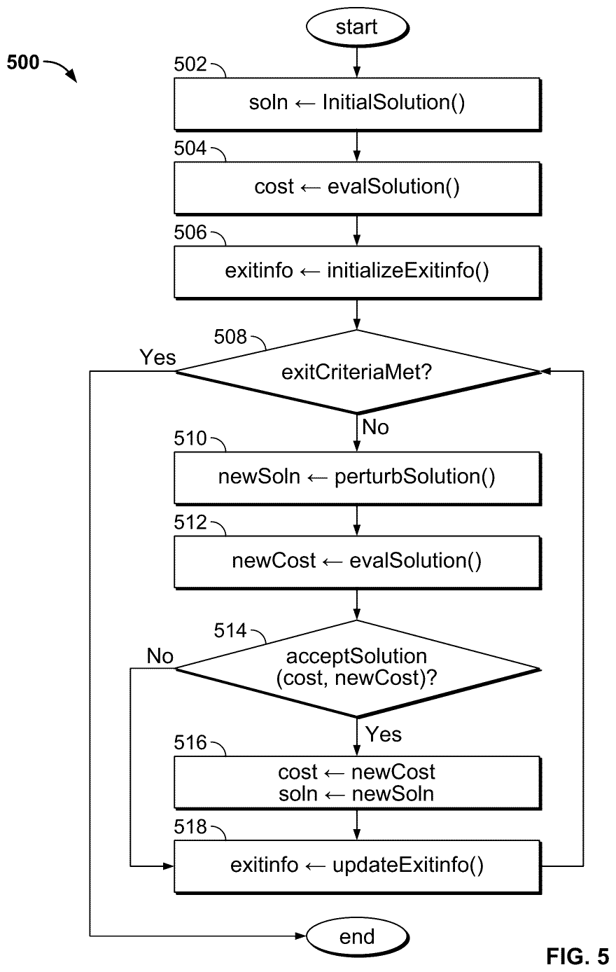

FIG. 4 illustrates an example system to select a codebook, in accordance with one or more embodiments of the present disclosure. In some embodiments, one or more statistics may be used to produce a codebook select signal (e.g., signal 306). In an example, diagram 400 illustrates the use of maximum exponent function 402. It will be understood that while functions are referenced, any function mentioned herein may be implemented using any suitable hardware described herein. For example, maximum exponent function 402 may be implemented using any suitable processing circuitry described herein.

In some embodiments, one or more values 204 may be sent to maximum exponent function 402 to determine a maximum exponent of one or more values 204. In some embodiments, statistics counter 404 may count a number of values of one or more value 204 that have exponents that match or are suitably similar to a result determined based on maximum exponent function 402.

In some embodiments, based at least in part on a count determined by statistics counter 404, where such a count indicates how many values of one or more values 204 match or are suitably similar to a result determined by maximum exponent function 402, at least one codebook of a plurality of codebooks may be selected. As such, signal 306, in some embodiments, may be based on results of statistics counter 404. In some embodiments, codebook selector 406 may generate signal 306.

In some embodiments, signal 306 generated by codebook selector 406 may be used to determine which encoding unit to use. For example, signal 306 may indicate to use encoding unit 310A in order to encode at least one value of one or more values 204.

In some embodiments, one or more of a plurality of codebooks may be selected. For example, a two-codebook setup may be provided where one codebook is optimized for a maximum exponent that is infrequent (e.g., with respect to a certain numerical distribution), and another codebook is optimized for a maximum exponent that is more frequent (e.g., with respect to the certain numerical distribution). In some embodiments, a first codebook may be suitable for a distribution that is more stretched, and a second codebook may be more suitable for a distribution that is more compact. Allocation of codes in each codebook may be determined based at least in part on which distribution captures a numerical distribution.

It will be understood that maximum exponent function 402 is merely illustrative, and any suitable statistic of one or more values (e.g., values 204) may be determined and counted by statistics counter 404. For example, instead of maximum exponent function 402 being used, another function may be used that counts sign bits which indicate positive or negative values.

Some operations may produce results that are entirely positive or negative by rendering the count of the sign bit equal to zero or equal to the size of the block. Selecting one or more codebooks between a plurality of different codebooks may be based at least in part on such a statistic. For example, a first codebook may be selected based on negative values, a second codebook may be selected based on positive values, and a third codebook may be selected based on a mix of both negative and positive values.

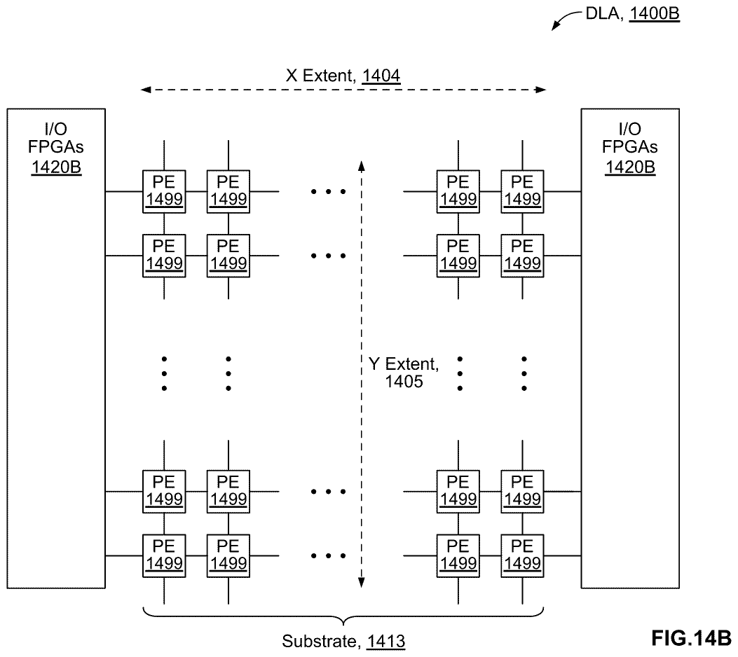

One or more heuristic optimization techniques may be used to create codebooks, such as based on an example process illustrated in FIG. 5. FIG. 5 is an example flowchart of a heuristic optimization algorithm to generate a codebook, in accordance with one or more embodiments of the present disclosure. In some embodiments, process 500 indicates how a heuristic optimization technique may be used to create one or more codebooks and includes steps 502-518, as illustrated, although in some embodiments, one or more steps may be omitted, modified, or appended in accordance with the present disclosure. Other steps not described in connection with FIG. 5 may be included as part of process 500 while still being in accordance with one or more embodiments disclosed herein. Furthermore, while the steps of process 500 are described as being performed by a processing element, the steps of process 500 may be implemented using any of the components described herein (e.g., further described below in connection with FIGS. 13-15).

In some embodiments, at step 502, a processing element may be configured to determine an initial solution. In some embodiments, a processing element may determine an initial solution based on sampling values from a distribution. For example, a processing element may determine an initial solution based on sampling values from one or more values 204. In some embodiments, a solution may be at least one of a codebook, a logic function, an encoding unit, a decoding unit, or combinations thereof. For example, a solution may be a codebook that is to be selected by signal 306 or codebook selector 406. In another example, a solution may be a encoding or decoding unit that corresponds to at least one of units 206, 210, 302A-302N, or 310A-310N.

In some embodiments, at step 504, a processing element may determine a cost associated with an initial solution. For example, a processing element may determine a root mean square error, mean square error, mean absolute error, any other suitable cost or loss function, or combinations thereof. Furthermore, at step 504, a processing element may determine a cost of a solution determined at step 502.

In some embodiments, at step 506, a processing element may determine whether a solution meets one or more exit conditions. An exit condition may be a root mean square error being below a threshold, a number of iterations exceeding a threshold, any other suitable condition indicating that a cost calculated at step 506 is sufficient to proceed, or combinations thereof. In some embodiments, a cost may be a reconstruction error describing an achieved error when converting between value types. In some embodiments, a cost and reconstruction error may be synonymous. As such, a reconstruction error may be a root mean square error when converting between values 204 and code 202, and vice versa.

In some embodiments, at step 508, a processing element may determine whether one or more exit criteria are met. For example, a processing element may determine whether one or more exit criteria are met at step 506. If one or more exit criteria are met, then process 500 may be completed. If one or more exit criteria are not met, then process 500 may proceed to step 510, as further described below.

In some embodiments, at step 510, a processing element may determine another solution different from a solution determined at step 502. In some embodiments, a processing element may determine another solution based on results of step 504. For example, a processing element may determine another solution that lessens a cost or loss determined at step 504.

In some embodiments, at step 512, a processing element may determine a cost associated with a solution. For example, a processing element may determine a cost associated with a solution determined during step 510. In some embodiments, a cost function used at step 512 may be the same as a cost function used at step 504. For example, a cost function used at both step 504 and 512 may be a root mean square error.

In some embodiments, at step 514, a processing element may determine whether to accept a solution. For example, a processing element may determine whether one or more exit criteria (e.g., where exit criteria of step 514 may include at least some of the same exit criteria as discussed above in connection with step 508) are met. If one or more exit criteria are not met, then process 500 may proceed to step 518 to update exit information. Exit information may include information indicating whether one or more exit conditions are satisfied such as whether one or more thresholds were exceeded, any other suitable type of information indicating whether to terminate process 500, or combinations thereof. In some embodiments, if one or more exist conditions are met, then process 500 may proceed to step 516.

In some embodiments, at step 516, a processing element may update at least one of cost information or a solution to use. For example, one or more data structures representing a cost or solution, respectively, may be updated. It will be understood that pointers, compressed representations, any other suitable type of information indicating a cost or solution, or combinations thereof may be used.

In some embodiments, at step 518, exit information may be updated. Exit criteria may be evaluated as in step 508. Once one or more exit criteria are satisfied, then process 500 may come to an end.

In some embodiments, process 500 may include a subset of steps 502-518 in any suitable combination. In some embodiments, process 500 begins by generating an initial solution (e.g., at step 502) and calculating a cost of an initial solution (e.g., at step 504). Process 500 may include iteratively refining one or more solutions. For example, any suitable number of solutions may be generated, and a corresponding number of cost functions may be determined for each of the generated solutions. In some embodiments, a solution may be altered (e.g., at step 510), and new candidate solutions may be produced. The cost of each candidate may be evaluated (e.g., at step 512). In some embodiments, one or more candidates may be accepted (e.g., at step 516) if such candidates meet certain criteria (e.g., at step 514). In some embodiments, process 500 may continue or occur any suitable number of times until one or more exit conditions (e.g., defined at step 506) are met.

In some embodiments, process 500 determines a solution or optimal cost iteratively based on one or more heuristics. For example, in some embodiments, a heuristic governing process 500 may be based on simulated annealing. In some embodiments, process 500 may utilize a temperature or any suitable parameter determining a risk an algorithm may take when determining a solution. For example, process 500 may use a temperature parameter to determine what subset of a search space to include when attempting to determine a solution. In some embodiments, process 500 may decrease a temperature parameter over time such that at high temperature values, process 500 may accept almost any change (e.g., to promoting exploration of various different solutions). In some embodiments, as a temperature lowers, process 500 may increasingly favor changes that improve more substantially improve a cost function to eventually determine an optimal solution. In some embodiments, process 500 may include performing suitable uphill estimations (e.g., generating a solution that increases a result of one or more cost functions). In some embodiments, process 500 may include performing one or more uphill estimations if such estimations may escape local minima.

In some embodiments, process 500 may utilize a plurality of heuristics. For example, process 500 may employ at least one of a process to minimize an error associated with a codebook (e.g., an error reduction process) or an error associated with a logic function (e.g., a logic complexity reduction process). In some embodiments, an error reduction process may include reducing, minimizing, or otherwise lessening a squared difference between the codebook entries and original data values. In some embodiments, a logic complexity reducing process includes assigning codes to values in a way that simplifies the complexity of decoding and/or encoding logic. Both heuristic processes may differ in how initial solutions are generated, how solution quality is evaluated, and/or how solutions are modified.

In some embodiments, an error reduction process may include determining an initial solution by sampling values from an original distribution. For example, an error reduction process may sample values from one or more values 204 and determining a distribution of one or more values 204. In some embodiments, an error reduction process may include modifying or generating new solutions (e.g., at step 510). For example, an error reduction process may include adjusting one or more values of a codebook (e.g., based on a cost function). In another example, an error reduction process may include replacing entries of a codebook with different values sampled from a data distribution. In some embodiments, an error reduction process may evaluate a codebook solution by encoding one or more values of a distribution using a given codebook and determining a square error with respect to an entire distribution.

In some embodiments, a logic complexity reduction process may include determining an initial solution by randomly assigning codes to values. In some embodiments, a logic complexity reduction process may include modifying a solution by selecting two codebook entries and swapping codes assigned to them. In some embodiments, a logic complexity reduction process may include determining a cost that represents logic complexity. For example, a cost may be determined based on a literal count in a sum-of-products form, which may serve as an estimate for the complexity of a resulting logic function.

In some embodiments, generating a codebook for a distribution that is implemented using logic functions may include employing an error reduction process and a logic complexity reduction process. In some embodiments, an error reduction process may include minimizing an error (e.g., an error based on an accuracy-compression tradeoff) that may be induced when using a codebook. In some embodiments, a logic complexity reduction process may be used to determine an assignment of codes to values that minimize the complexity of logic functions. In some embodiments, there may be multiple codebooks that achieve similar error levels, and one or more processes (e.g., heuristic processes) may be performed iteratively to generate multiple codebooks. One or more generated codebooks may be selected based on an estimated logic function complexity, such as a lowest estimated logic function complexity.

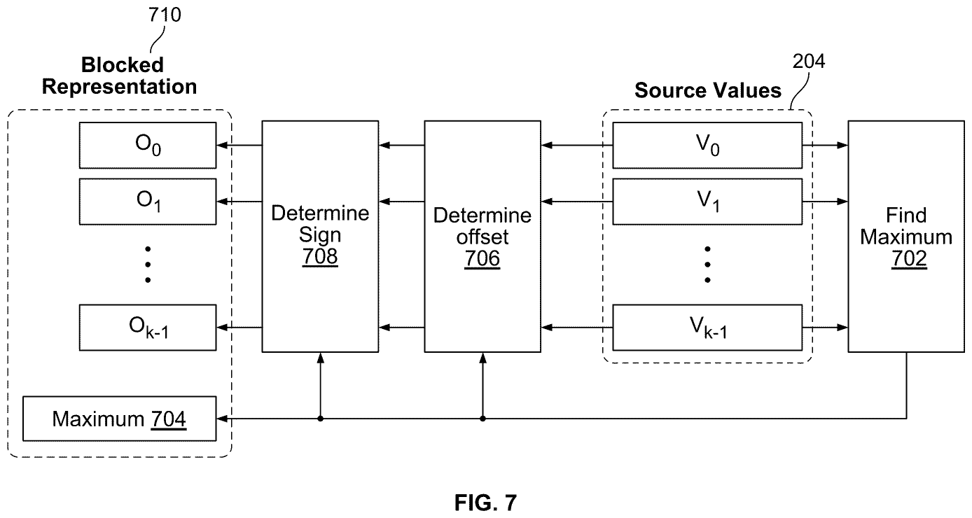

In some embodiments, some applications may be sensitive to outliers. In some embodiments, corresponding values may be represented using a low-bit-width data format based on blocking. A low-bit-width data format may be used for outlier preservation. An example of a data format based on blocking is illustrated in FIG. 6. FIG. 6 illustrates an example of a blocked numeric format that preserves outlier values, in accordance with one or more embodiments of the present disclosure.

As shown in diagram 600, within each block, values share common maximum value 602 stored in native precision (e.g., BF16, with 1 sign bit, 8 exponent bits (e.g., bits 608), and 7mantissa bits (e.g., bits 610)). In some embodiments, value 602 may be the greatest value in a given block. In some embodiments, by keeping the greatest value of a block in native precision, additional processing steps typically associated with outliers (e.g., as in other approaches) may be foregone.

In some embodiments, other values a block may be encoded as integer offsets 604 relative to value 602. For example, in some embodiments, subtracting an offset from the value 602 may recover an original value. In some embodiments, an offset calculation occurs entirely in the integer domain (e.g., without floating-point normalization adjusting the components of value 602).

In some embodiments, a structure of an integer offset may be configured. For example, bits for exponent and mantissa representations (e.g., 3 bits as shown in FIG. 6) may be configured to allow flexibility based on at least one of a desired compression, range, or precision. In some embodiments, a bits 606 (e.g., a signed bit) may indicate whether a sign of a value is the same or opposite to a sign of a maximum (e.g., value 602). A relative sign encoding may create a biased distribution of offsets (e.g., values with opposite signs often yield offsets greater than zero). In some embodiments, outliers may be preserved by encoding a maximum value based on all-zeros pattern 612, thereby allowing an original precision to be obtained upon decoding.

In some embodiments, a value may be represented by an offset larger than what may be stored. In some embodiments, a saturation process may be used. For example, if representing a value much smaller than a maximum requires an offset larger than what may be stored, then an offset is capped or otherwise saturated at a maximum representable value. In some embodiments, a maximum representable offset may be reserved to denote a zero value.

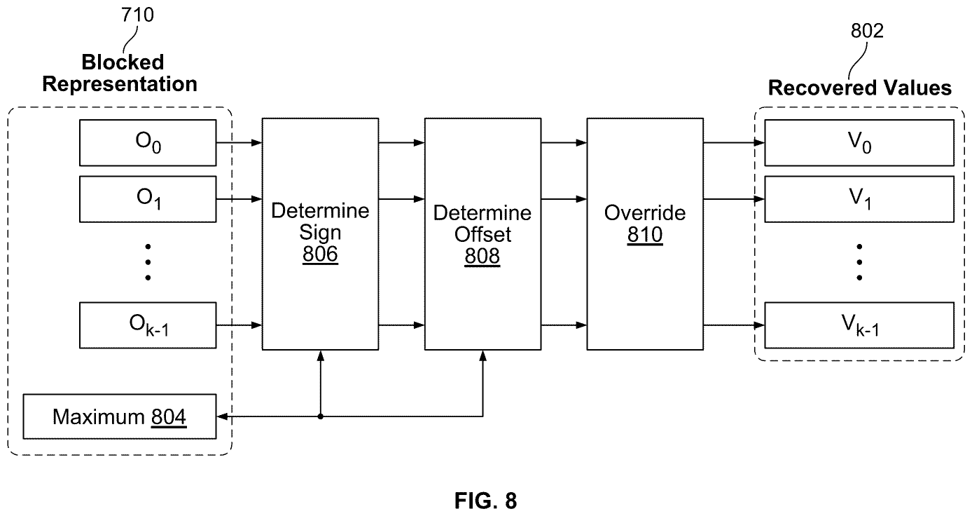

FIG. 7 depicts an example system to encode values into an outlier preserving blocked format, in accordance with one or more embodiments of the present disclosure. In some embodiments, FIG. 7 shows how one or more values 204 may be encoded based on a format as shown in FIG. 6 (e.g., where values are represented as offsets to a maximum).

In some embodiments, a processing element may determine maximum value 704, where maximum value 704 is the maximum value with respect to one or more values 204. In some embodiments, maximum value 704 may be determined based on maximum finder 702. It will be understood that any suitable statistic may be used in place of a maximum, and maximum finder 702 is named accordingly for the sake of example. In some embodiments, maximum value 704 may be stored based on its original precision in block representation 710.

In some embodiments, offsets 706 may be determined by subtracting each value of one or more values 204 from maximum value 704 and rounding to a suitable number of mantissa bits. In some embodiments, signs 708 may be determined for each of one or more values 204.

For example, it may be determined what an appropriate sign value is for each of one or more values 204, such that a sign is based on whether a sign value is the same or different than maximum value 704.

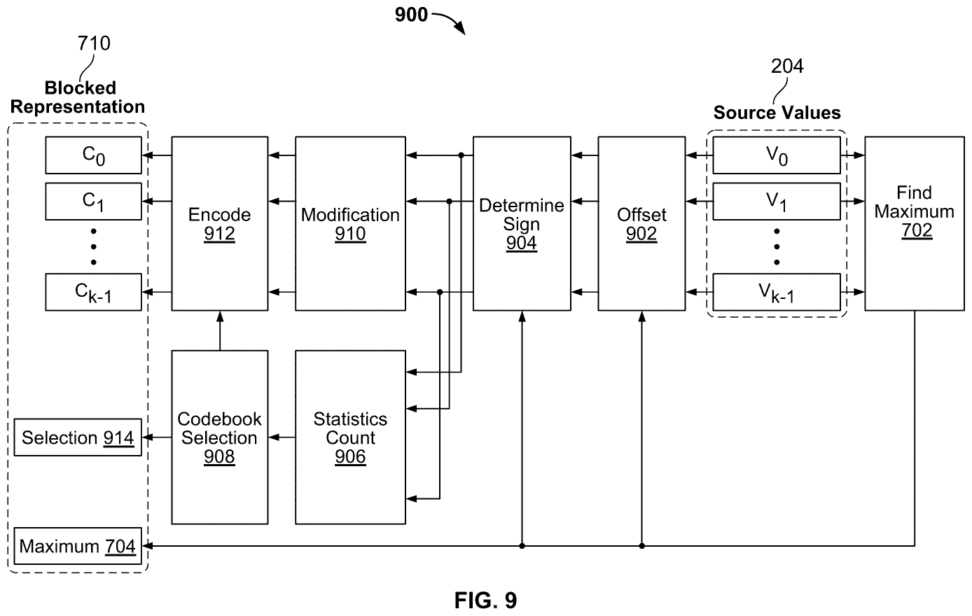

FIG. 8 depicts an example system to decode an outlier preserving blocked format into numerical values, in accordance with one or more embodiments of the present disclosure. In some embodiments, maximum value 804 (e.g., which may correspond to maximum value 704) may be stored based on block representation 710. In some embodiments, signs 806 (e.g., which may correspond to signs 806) for any value stored based on block representation 710 may be determined. For example, signs 806 may be based on determining whether a sign of a value matches or does not match with a sign of maximum value 804.

In some embodiments, offsets 808 (e.g., which may correspond to offsets 706) may be determined for any value stored based on block representation 710. In some embodiments, decoding may include override 810 if an offset applied was a maximum representable offset. For example, override 810 may be applied if an offset of offsets 808 was a maximum representable offset.

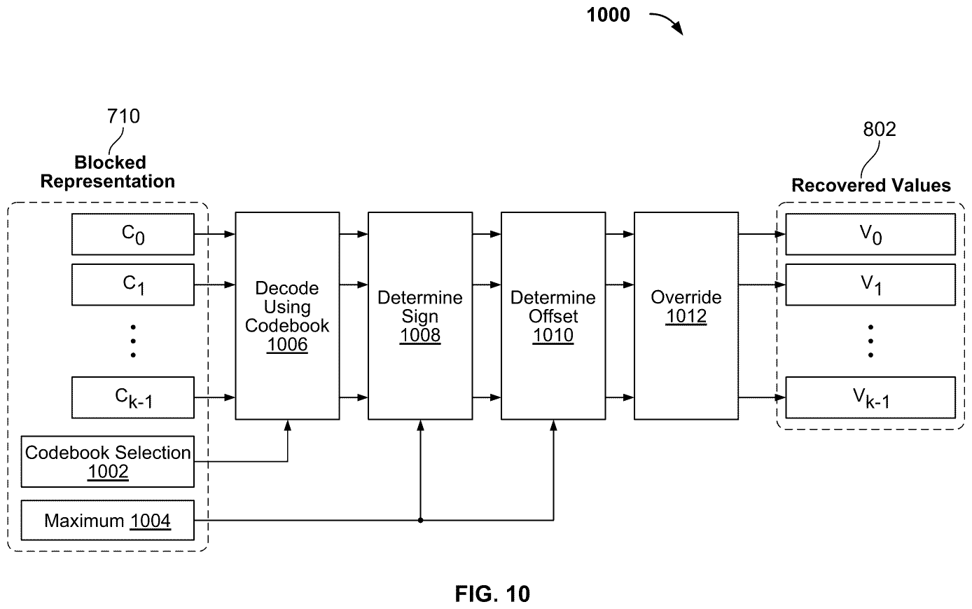

In some embodiments, processes for encoding and decoding described in the present disclosure may include one or more modifications. In some embodiments, a fixed number of offsets and sign bits to be encoded may have a particular distribution for which the codebooks may be adjusted and/or optimized during codebook construction. In some embodiments, a plurality of codebooks may be used where each codebook is tuned for a different distribution of the offsets and signs and may improve efficiency when selected for the corresponding distribution. An illustrative version of the blocked format encoding hardware is provided in FIG. 9.

FIG. 9 depicts an example system 900 to construct an outlier preserving blocked format based on a codebook, in accordance with one or more embodiments of the present disclosure. System 900 may include any structure of the encoding architecture previously described in connection with FIG. 7. In some embodiments, hardware 900 may be used to perform one or more operations related to encoding.

In some embodiments, hardware 900 includes statistics unit 906 and codebook selector unit 908. In some embodiments, statistics unit 906 may be configured to count the number of instances where any suitable criteria (e.g., a match in an exponent) is met for values of one or more values 204. In some embodiments, codebook selector unit 908 may be configured to determine signal 914 (e.g., which may correspond to signal 306), where signal 914 may be used to select a codebook used to encode and modify values. In some embodiments, signal 914 may be stored in block representation 710.

In some embodiments, system 900 may include modification unit 910 and encoding unit 912. In some embodiments, modification unit 910 may be configured to determine one or more modifications (e.g., where such modifications may correspond to those previously described in connection with modification 208). In some embodiments, modification unit 910 may be configured to encode a value (e.g., where such an encoding may be implemented based on logic function 210).

In some embodiments, system 900 may include any one or more of the following units: unit 902 configured to determine an offset of one or more values 204 with respect to maximum value 704, sign determining unit 904 configured to determine a sign of one or more values 204 with respect to maximum value 704, maximum finder 702 configured to determine a maximum value of one or more values 204, or any suitable combination thereof. It will be understood that each of units 902-912 and maximum finder 702 may be implemented using any suitable hardware, software, firmware, combinations thereof, or the like. Furthermore, the organization of system 900 as shown in FIG. 9 is merely illustrative, and any suitable organization of components of system 900 may still be in accordance with one or more embodiments disclosed herein.

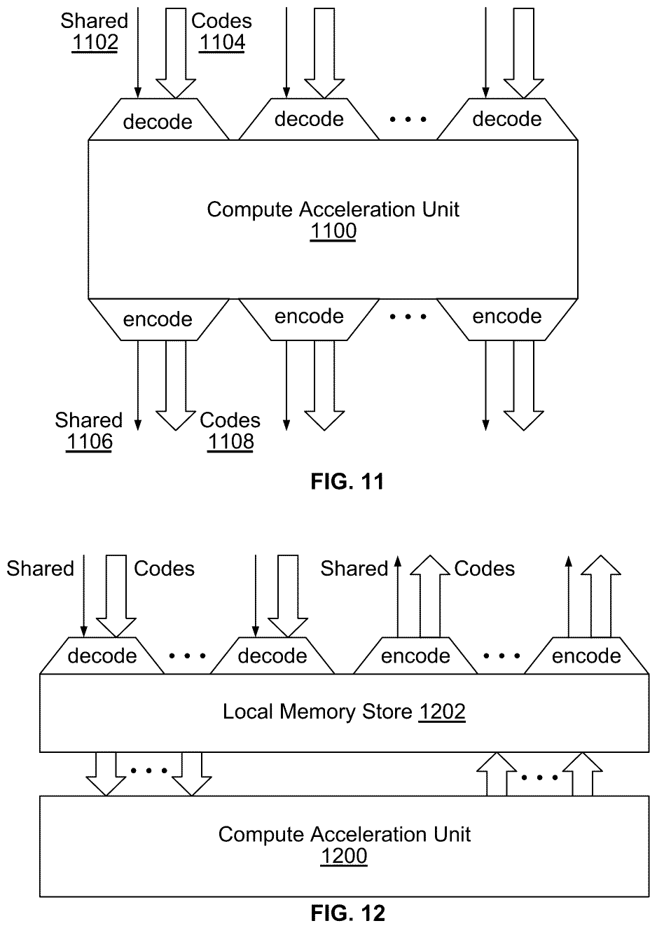

An example decoding hardware that reverses at least partially or all of the encoding is shown in FIG. 10. FIG. 10 depicts example system 1000 to recover values from an outlier preserving blocked format based on a codebook, in accordance with one or more embodiments of the present disclosure. System 1000 may include any structure of the encoding architecture previously described in connection with FIG. 8. In some embodiments, system 1000 may be used to perform one or more operations related to decoding.

In some embodiments, system 1000 includes at least units 1002 and 1006-1012. In some embodiments, codebook selection unit 1002 may be configured to select a codebook used to decode any value that is stored based on block representation 710. In some embodiments, decoding unit 1006 may be configured to decode any value stored based on block representation 710 using a codebook selected by codebook selection unit 1002. In some embodiments, sign determining unit 1008 (e.g., which may correspond to unit 904) may be configured to determine a sign of one or more values 204 with respect to maximum value 1004. In some embodiments, offset determining unit 1010 (e.g., unit 902) may be configured to determine an offset of one or more values 204 with respect to maximum value 1004. In some embodiments, unit 1012 (e.g., which may correspond to unit 902) may be configured to apply an override if an offset applied was a maximum representable offset. It will be understood that the organization of system 1000 as shown in FIG. 10 is merely illustrative, and any suitable organization of components of system 1000 may still be in accordance with one or more embodiments disclosed herein.

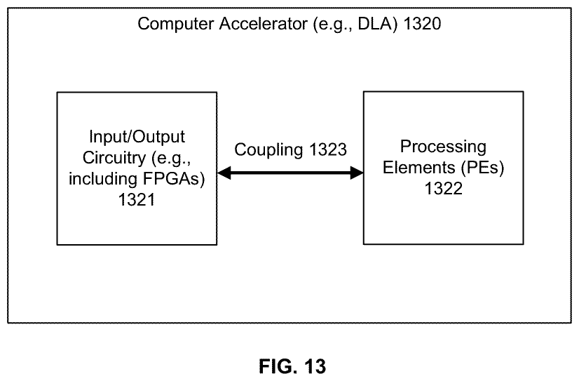

In some embodiments, encoding and decoding processes and/or a blocked numeric format described in the present disclosure may be applied when transporting data to and from compute acceleration units. For example, a compact representation of numerical data not only reduces, minimizes, or otherwise lessens bandwidth and storage needs, but also reduces the area and power of hardware for data movement and data storage. FIG. 11 illustrates an example setup where one or more input groups in a blocked numeric format are decoded before the numerical data enters the acceleration unit, and one more output groups are encoded into a blocked format as the data leaves the acceleration unit.

FIG. 11 depicts an example compute acceleration unit that uses blocked formats for its input and output, in accordance with one or more embodiments of the present disclosure. In some embodiments, compute acceleration unit 1100 may perform operations on data based on a decoded scheme and output data based on an encoded scheme. In some embodiments, shared portions of a blocked format (e.g., shared portion 1102 and codes 1104) are stored and transported as a separate entity from the codes that make up a block (e.g., shared portion 1106 and codes 1108). In some embodiments, shared data is moved together with codes as a single entity. In some embodiments, shared data is moved into and out of compute acceleration unit 1100 with separate instructions. In some embodiments, shared data is stored within compute acceleration unit 1100 during computation.

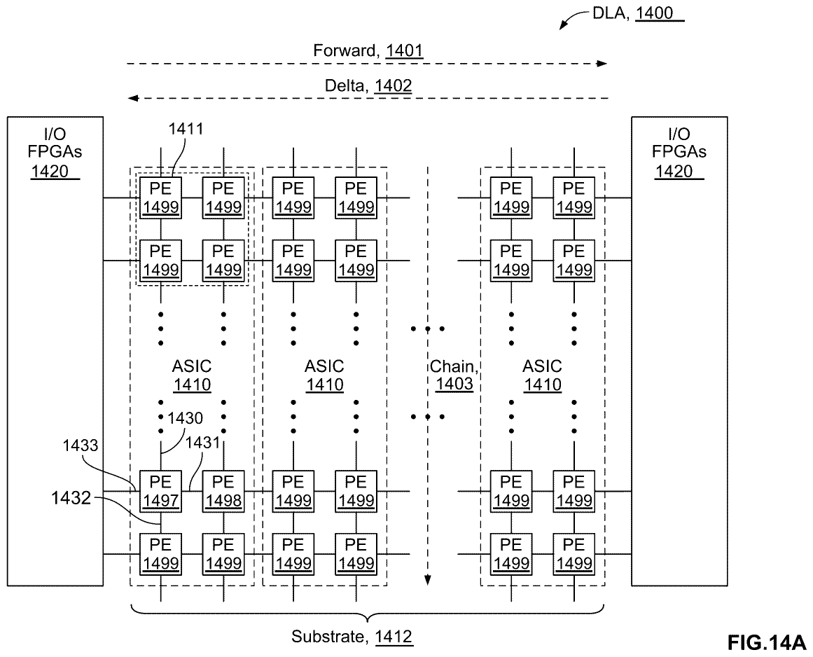

In some embodiments, a compute acceleration unit is not connected directly to each other, and/or one or more of compute acceleration units are connected to a local memory store. FIG. 12 depicts an example compute acceleration unit with an attached local memory store that uses blocked formats for its input and output, in accordance with one or more embodiments of the present disclosure. FIG. 12 depicts an example of a hardware compute acceleration unit with an attached local memory store that uses blocked formats for its input and output, in accordance with one or more embodiments of the present disclosure.

In some embodiments, compute accelerator unit 1200 (e.g., which may correspond to compute acceleration unit 1100) may transmit and receive data to local memory store 1202. For example, encoded data is decoded and deposited into local memory store 1202 where it is read by compute acceleration unit 1200. In some embodiments, results of computations by compute acceleration unit 1200 are written back to local memory store 1202. In some embodiments, after processing (e.g., when computations are complete), results are read out of local memory store 1202 and encoded into the blocked format before being sent out (e.g., to other compute acceleration units).

In some embodiments, CAUs 1100 and 1200 may be further described in connection with FIGS. 13-15. For example, the hardware described in connection with FIGS. 13-15 may be used to implement at least some of the functionality of at least one of CAUs 1100 or 1200. Furthermore, the hardware described in connection with FIGS. 13-15 may be used to implement or otherwise provide at least some functionality of any element, unit, device, or apparatus described herein. For example, the hardware described in connection with FIGS. 13-15 may be used to implement decoding unit 302A, selector 406, or the like. Additionally, the hardware described in connection with FIGS. 13-15 may be used to implement any suitable process described herein. For example, the hardware described in connection with FIGS. 13-15 may be used to implement process 500.

As referred to herein, references to a “substrate” are applicable to embodiments of a large substrate (e.g., a large-chip device, a large-substrate device, a rack-width substrate, printed circuit board (PCB), organic substrate, a whole or substantially whole wafer) as well as to embodiments of a significant portion of a substrate (e.g., a significant portion of a wafer).

In some embodiments, a compute accelerator may include one or more specialized components, such as processing elements, device components, or other hardware elements. Some implementations include one or more processing circuit elements such as transistors, resistors, inductors, capacitors, wire interconnects, combinatorial logic (e.g., NAND, NOR) gates, latches, register files, memory arrays, tags for memory arrays, content-addressable memories, flash, ROM, DRAM, SRAM, Serializer/Deserializer (SerDes), I/O drivers, and the like, such as implemented via custom logic, synthesized logic, ASICs, and/or FPGAs. Some example processing elements include one or more application specific integrated circuits (ASICs), such as central processing units (CPUs), graphics processing units (GPUs), tensor processing units (TPUs), or neural processing units (NPUs), including combinations and/or variants thereof. One or more compute accelerators may include processing elements coupled via a unifying compute fabric (“fabric” henceforth) and enabled to communicate with each other via the fabric. The processing elements and the fabric may be collectively referred to as a fabric of processing elements on a single compute accelerator or a plurality of compute accelerators coupled to each other.

In some embodiments, a processing element includes a router to communicate data packets (e.g., network packets or fabric packets) via the fabric and a CE to process the data packets. In some embodiments, a router may be coupled to a plurality of elements: a fabric, an off ramp to the compute element, and an on ramp from the compute element. In some embodiments, a coupling between the router and the fabric enables communication between the router and, e.g., four logically and/or physically adjacent processing elements. The router may receive data packets from the fabric and/or the on ramp. The router may transmit data packets to the fabric and/or the off ramp.

In some embodiments, a CE includes hardware elements that collectively execute the instructions based on receiving an associated data packet by performing operations specified by the instructions (e.g., arithmetic operations, control flow operations, and load/store operations). In some embodiments, the instructions are provided to the compute element separately from the associated data packet. Examples of the hardware elements include picker queues, a picker, a task definition table, an instruction sequencer, an instruction decoder, a data sequencer, a register file, a memory, a pseudo-random number generator, and an ALU. Some implementations of the hardware elements are in accordance with hardware logic circuitry elements as described elsewhere herein. A compute element may be referred to as a compute engine. A compute scheduler may be referred to as a picker, and a compute scheduler queue may be referred to as a picker queue. A CE may be enabled to process data packets by initiating tasks and executing instructions associated with the data packets, and accessing data associated with the data packets and/or the instructions. The instructions are in accordance with an instruction set architecture comprising arithmetic instructions, control flow instructions, datatype conversion instructions, configuration instructions, fabric management instructions, and load/store instructions. The instructions operate on operands comprising various datatypes, e.g., integer datatypes and floating-point datatypes of various widths. The operands may comprise scalar operands and/or vector operands. In various embodiments and/or usage scenarios, a vector may represent, e.g., weights of a neural network, inputs or stimuli of a neural network, activations of a neural network, and/or partial sums of a neural network. In some scenarios, a vector is a sparse vector (e.g., a vector of neuron activations) and comprises sparse data elements (e.g., only non-zero elements). In some other scenarios, a vector is a dense vector (e.g., pixel values) and comprises dense data elements (e.g., all elements of the vector, including zero elements).

In some embodiments, a fabric includes a collection of logical and/or physical couplings between processing elements and/or within a single processing element. The fabric may be configured to implement logical and/or physical communication topologies such as a mesh, a 2D mesh, a 3D mesh, a hypercube, a torus, a ring, a tree, or any combination thereof. An example of a physical coupling between processing elements is a set of physical interconnects (comprising optional and/or selective buffering) between physically-coupled processing elements. A first example of physically-coupled processing elements is immediately physically adjacent processing elements, such as a first processing element located directly beside (such as ‘north’, ‘south’, ‘east’, or ‘west’) of a second processing element. A second example of physically-coupled processing elements is relatively physically nearby processing elements, such as a first processing element located within a relatively small number of intervening processing elements, e.g., one or two ‘rows’ and/or ‘columns’ away from a second processing element. A third example of physically-coupled processing elements is relatively physically far away processing elements, such as a first processing element located physical relatively far away from a second processing element, such as a distance limited by signal propagation (with or without optional and/or selective buffering) within a clock cycle and/or clock sub-cycle associated with the processing elements. An example of physical coupling within a single processing element (having, e.g., a compute element and a router) is an on ramp coupling output information from the compute element to the router, and an off ramp coupling input information from the router to the compute element. In some embodiments, the router routes information from the on ramp to the off ramp. The router may route from the on ramp and through a number of zero or more hops to one or more consecutively adjacent routers and/or zero or more off-ramps (e.g., a plurality of off-ramps).

In some embodiments, memory or storage includes one or more elements enabled to retain state information, e.g., any one or more of: a flip-flop, a latch or an array of latches, a register or an array of registers, a register file, a memory, a memory array, a magnetic storage device, an optical storage device, SRAM, DRAM, flash, and ROM. In various embodiments storage is volatile (e.g., SRAM or DRAM) and/or non-volatile (e.g., flash or ROM).

In some embodiments, a compute accelerator may include wafer-scale integration by implementing a system using all or a significant portion of a large substrate as an element of the system, e.g., by leaving a large substrate whole or substantially whole. In some embodiments, wafer-scale integration enables connecting multiple elements in a system via substrate interconnects formed using semiconductor fabrication processes instead of via inter-chip interconnect, and may improves any one or more of improved performance, cost, reliability, and energy efficiency. As an illustrative example, a system implemented using wafer-scale integration technology enables implementation of more than one billion PEs on a single substrate, each of the PEs having bandwidth to nearest physical neighbors that is greater than a comparable system using other-than wafer-scale integration technology. The greater bandwidth enables the system implemented using wafer-scale integration technology to relatively efficiently train and/or perform inferences for larger neural networks than the system implemented using other-than wafer-scale integration technology.

In some embodiments, a logical coupling between processing elements includes a virtual channel as implemented by routers within processing elements. A route between a first processing element and a second processing element is implemented, e.g., by routers within processing elements along the route forwarding in accordance with the virtual channel and routing configuration information. An example of a logical coupling within a single particular processing element (having, e.g., a router) is a virtual channel as implemented by the router, enabling the particular processing element to send information via the virtual channel to the particular processing element. The router forwards with respect to the particular processing element in accordance with the virtual channel and routing configuration information.

In some embodiments, a data packet (e.g., fabric packets or network packets) includes a bundle of information communicated between processing elements via the fabric. In some embodiments, a data packet may include one or more fields indicative of a payload and/or a virtual channel (e.g., a virtual channel identifier). A payload may include data and may be associated with instructions. For example, a first response to a data packet received by a compute element of a processing element may include the compute element initiating a task, such as corresponding to processing of instructions associated with the data packet. For example, a second response to a data packet received by a compute element of a processing element may include the compute element processing data of the data packet. Some example types of data packets include dense packets and sparse packets, as well as data-type and control-type.

Data packets may be used, for example, for communicating between processing elements. For example, a first processing element may transmit data packets to a second processing element. For example, an external device (e.g., an FPGA) may transmits data packets to a processing element. For example, a processing element transmits data packets to an external device (e.g., an FPGA).

In some embodiments, a virtual channel includes one or more communication pathways specified by a virtual channel identifier (e.g., a color field) and may be enabled, e.g., by a fabric and one or more routers. A data packet including a particular virtual channel identifier is sometimes referred to as being associated with a particular virtual channel (e.g., associated with a particular color). A first example of a color is a fabric color specifying a virtual channel between two different processing elements. In some embodiments, a fabric color is a 5-bit integer. A second example of a color is a local color specifying a virtual channel from a processing element to the processing element. In some embodiments, a color is a 6-bit integer and specifies one of a fabric color and a local color.

An example task may include a collection of instructions executed in response to a data packet. An example instruction may include an operation and optionally one or more operands specifying locations of data elements to be processed in accordance with the operation. A first example of an operand specifies data elements in memory. A second example of an operand specifies data elements communicated (e.g., received or transmitted) via the fabric. An example of a data sequencer determines the locations of data elements. An example of an instruction sequencer determines an address in memory of instructions associated with a data packet.

An example picker queue is enabled to hold data packets received via an off ramp of the fabric for processing in the compute element. An example of a picker selects a data packet from the picker queue for processing, and/or selects an active unblocked virtual channel identifier for processing to initiate a corresponding task.

An example of storage is one or more elements enabled to retain state information, e.g., any one or more of: a flip-flop, a latch or an array of latches, a register or an array of registers, a register file, a memory, a memory array, a magnetic storage device, an optical storage device, SRAM, DRAM, flash, and ROM. In various embodiments storage is volatile (e.g., SRAM or DRAM) and/or non-volatile (e.g., flash or ROM).

An example of an Integrated Circuit (IC) is a collection of circuitry implemented on one or more portions of semiconductor material, such as a single die or a plurality of dies. An example of 3D-stacking of dies is providing mechanical connectivity and/or electrical connectivity between the dies, e.g., in a dimension orthogonal to a major surface of the dies, to form a unit. The mechanical connectivity and/or the electrical connectivity may be implemented, e.g., via one or more of solder balls, microbumps, hybrid bonds, and through-substrate vias. An example of 2.5D stacking of dies is providing mechanical connectivity and/or electrical connectivity between the dies via a common element (e.g., an interposer) to form a unit, wherein the mechanical connectivity and/or electrical connectivity between each die and the substrate is in a dimension orthogonal to a major surface of the die. The mechanical connectivity and/or the electrical connectivity may be implemented, e.g., via one or more of solder balls, microbumps, and through-substrate vias. An example of an Application-Specific Integrated Circuit (ASIC) is an IC designed for a particular use.

An example of a package is an element enabled to mechanically retain and/or contain one or more electronic circuits and/or to electrically interconnect one or more electronic circuits. Example electronic circuits are any one or more of one or more portions of semiconductor material, one or more dice, one or more interposers, and one or more substrates. Particular examples of packages include a BGA package and variants thereof. Some ICs comprise a package. An example of a substrate is an element to mechanically retain and/or electrically interconnect one or more dice and/or one or more packages. An example of a substrate includes a PCB, to, e.g., retain and interconnect packages. An example of a substrate includes an interposer to, e.g., couple one or more 3D-stacked or 2.5-stacked dice. An example of a substrate includes a package, e.g., retaining a plurality of dice.

An example of inter-package communication is communication between packages, e.g., between a first package and a second package. A particular example of inter-package communication is communication between a first BGA mounted on a PCB and a second BGA mounted on the PCB. An example of intra-package communication is communication within elements of a package. A particular example of intra-package communication is communication between a first die in a package and a second die in the package. An example of intra-substrate communication is communication between elements of a substrate, such as between a first package mounted on a PCB and a second package mounted on the PCB. An example of inter-die communication is communication between dice, such as between a first 3D-stacked die of a package and a second 3D-stacked die of the package. Some inter-die communication is in accordance with intra-package communication. Some inter-die communication is in accordance with intra-substrate communication. An example of intra-die communication is communication between elements of a same die, such as between electrically interconnected routers of a same die.

FIG. 13 shows a block diagram illustrating an example compute accelerator, such as a deep learning accelerator (DLA) 1320. In some embodiments, DLA 1320 includes FPGAs 1321 and PEs 1322, enabled to communicate with each other, as illustrated by coupling 1323. One or more servers, user devices, and/or other systems may be communicatively coupled to DLA 1320. DLA 1320 is enabled to perform processing (e.g., training and/or inference) with neural networks, such as by computing weights in response to placement information and training information. DLA 1320 is further enabled to provide the weights as results via one or more communication paths. PEs 1322 comprise a relatively large number of PEs (e.g., 10,000 or more) each enabled to independently perform routing and computations relating to training. In some embodiments and/or usage scenarios, PEs 1322 is implemented via wafer-scale integration, such as respective pluralities of PEs implemented on respective dice of a single wafer. FPGAs 1321 are enabled to interface PEs 1322 to information provided via one or more communication paths. The interfacing includes conversion to/from a first data structure (e.g., modified Ethernet frames or network packets) from/to a second data structure (e.g., fabric packets or wavelets), as communicated on Coupling 1323. In various embodiments and/or usage scenarios, an example of processing the information comprises quantizing model weights or other values (e.g., converting from a floating-point number format to a fixed-point number format, encoding numerical values, or decoding values in a block numeric format).

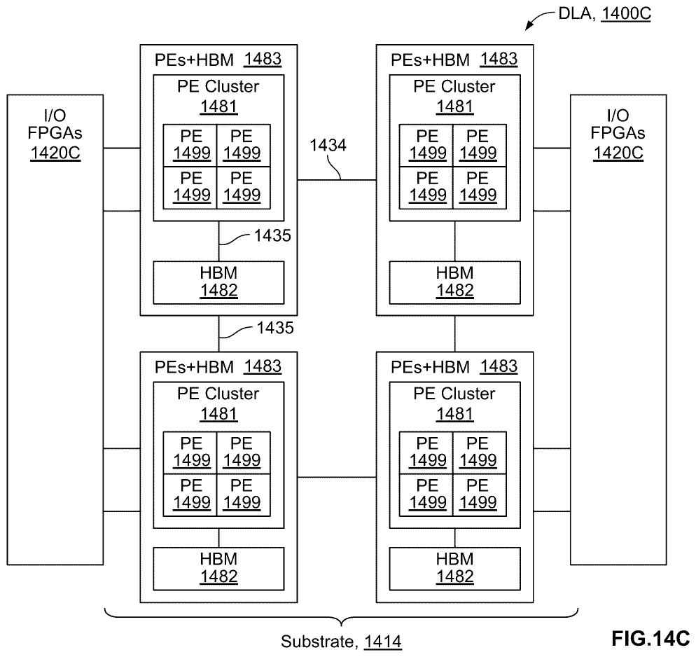

FIG. 14 shows block diagrams illustrating some example configurations of a compute accelerator as DLA 1400, 1400B, and 1400C. Each of PE 1499 elements has couplings to other of PE 1499 elements. Two of the PE elements (PE 1497 and PE 1498) are illustrated with unique identifiers and are otherwise respectively identical to instances of PE 1499. PE 1497 is illustrated with identifiers for each of four couplings (North coupling 1430, East coupling 1431 with PE 1498, and South coupling 1432) to others of the PEs and one of the I/O FPGAs (West coupling 1433), but is otherwise identical to others of the PE elements illustrated. In some embodiments and/or usage scenarios, the couplings are logical and/or physical. In various embodiments and/or usage scenarios, the couplings are usable to communicate data packets, backpressure information, or both. In various embodiments and/or usage scenarios, all or any portions of the physical couplings are to physically adjacent PEs. In some embodiments and/or usage scenarios, the PEs are physically implemented in a 2D grid. In some embodiments and/or usage scenarios, the PEs are physically implemented in a 2D grid of aligned rectangles, and physically adjacent PEs correspond to PEs sharing a horizontal boundary (North/South PEs with respect to each other) and PEs sharing a vertical boundary (East/West PEs with respect to each other).

In some embodiments and/or usage scenarios, an array of identical instances of a same ASIC is formed on a wafer, and each of the same ASICs comprises a plurality of identical instances of a same PE (e.g., PE 1499), forming a wafer (e.g., Wafer/substrate 1412) usable in wafer-scale integration techniques. Unless indicated to the contrary, references herein to a “wafer” (including to Wafer 1412) are applicable to embodiments of a whole or substantially whole wafer as well as to embodiments of a significant portion of a wafer. It will be understood that depending on the context, wafer 1412 may be referred to as substrate 1412, and vice-versa. In some embodiments and/or usage scenarios, one or more peripheral portions of the PEs are coupled to I/O FPGAs 1420A. Example ASICs are illustrated as ASIC 1410, comprising a column-organized section of PEs (replicated, e.g., in a one-dimensional fashion to form a wafer), and ASIC 1411, comprising a square-organized section or a rectangular-organized section of PEs (replicated, e.g., in a two-dimensional fashion to form a wafer). Other organizations of ASICs on a wafer are contemplated.

In some embodiments and/or usage scenarios, neurons associated with layers in a neural network are generally placed on PE 1499 elements in a left to right fashion, with earlier layers (e.g., the input layer) on the left and subsequent layers (e.g., the output layer) on the right. Accordingly, data flow during training is illustrated conceptually as dashed-arrows Forward 1401, Delta 1402, and Chain 1403. During Forward 1401, stimuli are applied to the input layer and activations from the input layer flow to subsequent layers, eventually reaching the output layer and producing a forward result. During Delta 1402, deltas (e.g., differences between the forward result and the training output data) are propagated in the backward direction. During Chain 1403, gradients are calculated based on the deltas (e.g., with respect to the weights in the neurons) as they are generated during Delta 1402. In some embodiments and/or usage scenarios, processing for Delta 1402 is substantially overlapped with processing for 1403.

In some embodiments and/or usage scenarios, any of DLAs 1400A-1400C is an implementation of DLA 120 of FIG. 13. In some embodiments and/or usage scenarios, individual PE 1499 elements correspond to individual PEs of PEs 1322 of FIG. 13. In some embodiments and/or usage scenarios, each ASIC 1410 element or alternatively each ASIC 1411 element corresponds to all or any portions of PEs of PEs 1322 implemented as individual integrated circuits. In some embodiments and/or usage scenarios, each ASIC 1410 element or alternatively each ASIC 1411 element corresponds to (optionally identical) portions of PEs 1322 implemented via respective dice of a wafer. In some embodiments and/or usage scenarios, I/O FPGAs 1420A-1420C elements may correspond to FPGAs 121 of FIG. 13.

DLA 1400B comprises an array of instances of PE 1499 as Substrate 1413. DLA 1400B further comprises instances of I/O FPGAs 1420B that one or more peripheral portions of the PEs are coupled to. Each of PE 1499 elements has couplings to at least some other of PE 1499 elements. Couplings between the PEs are, in various embodiments, similar or identical in nature to the couplings between the PEs of DLA 1400A. The individual PEs are, in various embodiments, physically and/or logically implemented similarly to or identically to the PEs of DLA 1400A; however, X-Extent 1404 and Y-Extent 1405 vary according to embodiment.

Varying the X-Extent and the Y-Extent according to embodiment enables scaling up (or down) compute capacity and storage capacity in tandem, enabling various price/performance implementations. For a first example, X-Extent 1404 is 700, corresponding to 700 PEs in the X dimension, and Y-Extent 1405 is 700, corresponding to 700 PEs in the Y dimension. Thus, in the first example, there are 490,000 PEs. For a second example, X-Extent 1404 is 1750, corresponding to 1750 PEs in the X dimension, and Y-Extent 1405 is 1750, corresponding to 1750 PEs in the Y dimension. Thus, in the second example, there are 3,062,500 PEs. Other examples have differing X-and Y-Extents.

In various embodiments, Substrate 1413 comprises any one or more of an entire wafer, a portion of a wafer, a single ASIC, a plurality of ASICs, a plurality of dice, a plurality of 3D-stacked dice, and a PCB comprising one or more of the foregoing. For a first example, Substrate 1413 comprises a portion of a wafer corresponding to a largest rectangle, according to physical granularity of the PEs, fitting inside an entire substantially circular wafer. For a second example Substrate 1413 comprises N by M ASICs coupled via a PCB, each ASIC comprising A by B PEs. Thus, in the second example, the X-Extent is N times A, the Y-Extent is M times B, and there are N times A times M times B PEs.

In some embodiments of a scaled compute fabric for a compute accelerator, the PEs are identical to the PEs of DLA 1400A, as indicated by the like element identifiers of the PEs (PE 1499) in DLA 1400A and DLA 1400B. In some embodiments (not illustrated), the PEs of DLA 1400B are variations on the PEs of DLA 1400A. For example, the PEs of DLA 1400B may have a different amount of memory than the PEs of DLA 1400A. For another example, the PEs of DLA 1400B comprise differing coupling technology than the PEs of DLA 1400A. For yet another example, the PEs of DLA 1400B are implemented to use more power than the PEs of DLA 1400A, enabling, e.g., operation at a higher frequency. For yet another example, the PEs of DLA 1400B are implemented to use less power than the PEs of DLA 1400A, restricting, e.g., operation to a lower frequency.

In a first specific example of an embodiment of a scaled compute fabric for a compute accelerator (e.g., a deep learning accelerator), PEs are arranged and interconnected similar to either of DLA 1400A or DLA 1400B, and the PEs are implemented with more memory than the PEs of DLA 1400A. In some circumstances, embodiments in accordance with the first specific example enable higher performance (albeit at a higher cost) than embodiments in accordance with either of DLA 1400A or DLA 1400B. In some conditions, the higher performance is enabled, e.g., by increased local storage of weights, such as in a context of larger neural networks.

In a second specific example of an embodiment of a scaled compute fabric for a compute accelerator (e.g., a deep learning accelerator), PEs are arranged and interconnected similar to either of DLA 1400A or DLA 1400B, and there are fewer PEs than in either DLA 1400A or DLA 1400B. In some circumstances, embodiments in accordance with the second specific example enable lower cost (albeit at a lower performance) than embodiments in accordance with either of DLA 1400A or DLA 1400B. In some conditions, the lower cost is enabled by using a smaller wafer due to fewer PEs.

In a third specific example of an embodiment of a scaled compute fabric for a compute accelerator (e.g., a deep learning accelerator), PEs are arranged and interconnected similar to either of DLA 1400A or DLA 1400B, the PEs are implemented with more memory than the PEs of DLA 1400A, and there are fewer PEs than in either DLA 1400A or DLA 1400B. In some circumstances, embodiments in accordance with the third specific example enable either of lower cost or higher performance, depending on computation versus storage requirements for a particular application. In some conditions, the lower cost is enabled by reducing the number of PEs so that even with the larger memory using a smaller wafer is possible. In some conditions, the higher performance is enabled for neural networks with more weights than simultaneously storable in the compute accelerator (e.g., the deep learning accelerator) without the larger memory.

DLA 1400C comprises an array of instances of processing regions including one or more PEs and/or one or more memories (e.g., high-bandwidth memory (HBM) or other types of memory). It is noted that one or more regions (e.g., labeled as PEs+HBM 1483) are provided as an illustrative example including PEs illustrated as a two-by-two array for clarity as part of Substrate 1414. It is noted that the referenced parts of FIG. 14 are labeled as, e.g., PEs+HBM 1483 and/or HBM 1482 for illustrative purposes in the following paragraphs and are intended to be non-limiting. DLA 1400C further comprises instances of I/O FPGAs 1420C that one or more peripheral portions of the instances of PEs+HBM 1483 are coupled to. Each of the PEs+HBM 1483 instances has couplings to at least some others of the PEs+HBM 1483 elements, as illustrated conceptually by (representative) Horizontal coupling 1434 and (representative) Vertical coupling 1435. PEs+HBM 1483 comprises PE Cluster 1481 coupled to HBM 1482 as illustrated conceptually by (representative) PE Cluster and HBM coupling 1436. Each of the PEs of PE Cluster 1481 has shared access to HBM 1482 via PE Cluster and HBM coupling 1436. PE Cluster 1481 comprises an array of instances of PE 1499 (for clarity illustrated as a two by two array). The individual PEs are, in various embodiments, physically and/or logically implemented similarly to or identically to the PEs of DLA 1400A.

Within an instance of PE Cluster 1481, PE 1499 elements are coupled to each other similarly or identically in nature to the PEs of DLA 1400A. The couplings between the PEs enable communication of data packets, backpressure information, or both, as in DLA 1400A. The couplings between the instances of PEs+HBM 1483 (e.g. via Horizontal coupling 1434 and/or Vertical coupling 1435) enable communication of data packets between the instances of PEs+HBM 1483 and/or on behalf of the PEs comprised therein. In some embodiments, one or more formats of data packets communicated via the couplings between the instances of PEs+HBM 1483 are similar to or identical to one or more formats of data packets communicated via the couplings between the PEs. In some embodiments, one or more data packets communicated via the couplings between the instances of PEs+HBM 1483 correspond to and/or are in accordance with respective data packets communicated via the couplings between the PEs. For example, a first instance of PEs+HBM 1483 comprises two instances of PE 1499. A data packet communicated between the two instances of PE 1499 is encapsulated for further communication to a second instance of PEs+HBM 1483. In some embodiments, some of the formats of the data packets communicated via the couplings between the instances of PE 1499 and/or between the instances of PEs+HBM 1483 comprise a packet payload, an indicator, and/or an instruction.

In some embodiments, data packets are communicated relatively more in parallel between PEs of a PE cluster than between PE clusters. For example, the couplings between PE 1499 elements enable communication of an entire data packet (in at least some circumstances) in a single clock cycle via a parallel transfer of a plurality of bits on a plurality of physical wires. Continuing with the example, the couplings between the instances of PEs+HBM 1483 (e.g. Horizontal coupling 1434 and/or Vertical coupling 1435) enable communication of a data packet over a plurality of clock cycles via a serial transfer of the bits of the data packet. In some implementations in accordance with the example, the clock for the parallel transfer and the clock for the serial transfer are multiples of each other so that bandwidth of the parallel transfer and the serial transfer are identical, or alternatively an integer multiple of one another.

In various embodiments, Substrate 1414 comprises differing extents of instances of PEs+HBM 1483 in horizontal and/or vertical dimensions. In various embodiments, PE Cluster 1481 comprises differing extents of instances of PE 1499 in horizontal and/or vertical dimensions. Embodiments with differing numbers of instances of PEs+HBM 1483 and/or differing numbers of instances of PE 1499 enable design reuse of components in various price/performance implementations.

In various embodiments, one or more of PE Cluster 1481, HBM 1482, PEs+HBM 1483, and Substrate 1414, comprise any one or more of an entire wafer, a portion of a wafer, a single ASIC, a plurality of ASICs, a plurality of dice, a plurality of 3D-stacked dice, a plurality of 2.5D-stacked dice, and a PCB comprising one or more of the foregoing. In some embodiments, PE Cluster 1481 and HBM 1482 comprise 3D-stacked dice, such as, one or more dice corresponding to PE Cluster 1481, and one or more dice corresponding to HBM 1482. For example, PE Cluster 1481 is implemented with one or more PE dice, HBM 1482 is implemented with one or more DRAM dice and an HBM controller die, and PEs+HBM 1483 is implemented by 3D-stacking the PE dice, the DRAM dice, and the HBM controller die. In various embodiments, PEs+HBM 1483 is implemented by 2.5D-stacking two or more of the PE dice, the DRAM dice, and the HBM controller die to a common silicon interposer. In some embodiments, HBM 1482 implements storage via dynamic storage cells. In some embodiments and/or usage scenarios, HBM 1482 is compatible with one or more standards adopted by JEDEC. In some embodiments and/or usage scenarios, PE Cluster and HBM coupling 1436 is compatible with one or more HBM interface standards adopted by JEDEC.

In various embodiments and/or usage scenarios, any one or more of the horizontal couplings between instances of PEs+HBM 1483 (e.g., as illustrated by Horizontal coupling 1434), and/or any one or more of the vertical couplings between instances of PEs+HBM 1483 (e.g., as illustrated by Vertical coupling 1435) are implemented by a plurality of high-speed serial couplings, e.g., SerDes couplings, sometimes referred to as SERDES techniques.

Consider a specific exemplary embodiment of a scaled compute fabric for a compute accelerator (e.g., a deep learning accelerator) in accordance with DLA 1400C that simultaneously considers memory capacity, memory bandwidth, and communication bandwidth. HBM 1482 comprises an HBM2 3D stack providing 4 GB of non-local memory capacity at 2 Tb/s bandwidth via PE Cluster and HBM coupling 1436. PE Cluster 1481 comprises 64 instances of PE 1499 on a die, each PE with 48 KB of local memory and operable at 500 MHz. PEs+HBM 1483 comprises the HBM2 3D stack 3D-stacked on top of the PE die in a BGA package with approximately 800 pins and dissipating approximately 20 watts during operation. There is 4 GB/64=64 MB of non-local memory capacity per PE. Substrate 1414 comprises a PCB with instances of I/O FPGAs 1420C and an array of up to 1000 instances of PEs+HBM 1483 mounted and coupled thereon. Horizontal coupling 1434 and Vertical coupling 1435 link together the instances of PEs+HBM 1483 and collectively comprise 42 15 Gb/s SERDES channels per instance of PEs+HBM 1483. A multidimensional interconnect graph is used for communication between the instances of PEs+HBM 1483 resulting in a sublinear (versus PE count) interconnect bandwidth.

The area of the PE cluster die is approximately 10 mm^2, and the power dissipation of 32-128 PEs is approximately 1-4 watts. Each PE sustains 64 bits per cycle in/out for communication with the non-local memory and 320 bits per cycle in/out for communication via the SERDES channels.

The local memory (e.g., 48 KB) of each PE may be used to store instructions and data, such as parameters and activations. The instructions and/or data are paged in and out of the local memory of each PE from and to the non-local memory under control of software executing on the respective PE, thus using the local memories as software managed caches for the PEs.

In some embodiments and/or usage scenarios, the PEs of any of DLA 1400A-1400C are conceptually partitioned into compute and storage roles by configuring and/or programming such that a fraction of the PEs substantially or entirely perform computation and the remainder of the PEs substantially or entirely perform operand storage. For example, 50% of the PEs perform computation and operand storage. The remaining 50% of the PEs perform operand storage, providing operands to and receiving results from the other 50% of the PEs. In some conditions, the partitioning enables decreased power consumption. In some conditions, the decreased power consumption is obtainable with relatively little reduction in performance, e.g., for neural networks having relatively lower compute requirements and/or relatively higher storage requirements. In some scenarios, the partitioning enables increased yield, e.g., PEs with manufacturing defects in computational logic are configured for operand storage.

As illustrated, e.g., in DLA 1400A, a compute accelerator may comprise a plurality of PEs coupled to each other via a fabric. Each PE includes a CE (e.g., for performing computations) and a router (e.g., for managing and/or implementing movement of information on the fabric).

The fabric operates as a communication interconnect between all the PEs in the compute accelerator (e.g., the deep learning accelerator). The fabric transfers data packets, e.g., via 30-bit physical couplings to enable transfer of an entire data packet per cycle (e.g., core clock cycle). Conceptually the fabric is a local interconnect distributed throughput the PEs such that each PE is enabled to communicate directly with its (physical) neighbors. Communication to other-than (physical) neighbors is via hops through intermediate nodes, e.g., others of the PEs. In some embodiments and/or usage scenarios, a distributed local fabric topology efficiently maps to a neural network workload, e.g., each layer sends data to a neighboring layer) and/or is implementable with relatively lower cost in hardware.

As illustrated in DLA 1400A, an example (physical) fabric topology comprises a 2D mesh with each hop in the X or Y dimension (e.g. West 1433 or North 1430 of FIG. 14A, respectively) performed in a single core clock cycle. In addition to the 2D mesh illustrated, some embodiments further comprise “skip” connections, e.g., in the horizontal dimension and “loop” connections, e.g., in the vertical dimension. An example skip connection enables PEs in a same row of the 2D mesh and physically separated by N other PEs to communicate with each other as if the PEs were physically adjacent. A hop along a skip connection (e.g. Skip West 1433 of FIG. 14A) is performed in a single core clock cycle. In various embodiments, an example loop connection enables a PE at the bottom of a column of PEs to communicate with a PE at the top of the column as if the PEs were physically adjacent. In some embodiments, a hop along a loop connection is performed in a single core clock cycle.

Performing each hop in the X or Y dimension in a single clock, in some embodiments and/or usage scenarios, enables simplifying implementation of arbitrary programmable routing topologies and related timing constraints. In some circumstances, the single cycle per hop latency is compatible with an associated pipelined data flow pattern. In some circumstances (e.g., when communicating from one layer to a next layer), the single cycle per hop latency adds additional latency and reduces performance. The additional latency is worst when the layer is deep and uses many PEs, since more hops are used to escape the layer and to reach all the PEs of the next layer. The additional latency results in overall workload pipeline length increasing and therefore storage (e.g. for forward pass activations) increasing.

The skip connections are used to reduce the additional latency. Consider an example. Each skip connection skips 50 PEs in a single core clock cycle. The latency to enter the first skip connection is 49 hops maximum. The latency to reach a final PE after exiting a final skip connection is 49 hops maximum. Therefore, there is a 98-core clock cycle maximum latency overhead and a 49-core clock cycle average latency overhead. The latency to process a layer is 2000 core clock cycles. Thus, in the example, there is a 5% maximum overall overhead and a 2.5% average overall overhead.

In some embodiments and/or usage scenarios, each row has skip connections and each column has loop connections. In some embodiments and/or usage scenarios, each skip connection skips 50 PEs, and each column has 200 PEs that a loop connection encompasses. In some embodiments, a single loop connection (e.g., in a context of a column of PEs, between the PE at the bottom of the column and the PE at the top of the column) approximately physically spans the column, and in other embodiments, loop connections of the column are physically implemented by folding so that the average and worst case loop hops approximately physically span two PEs.

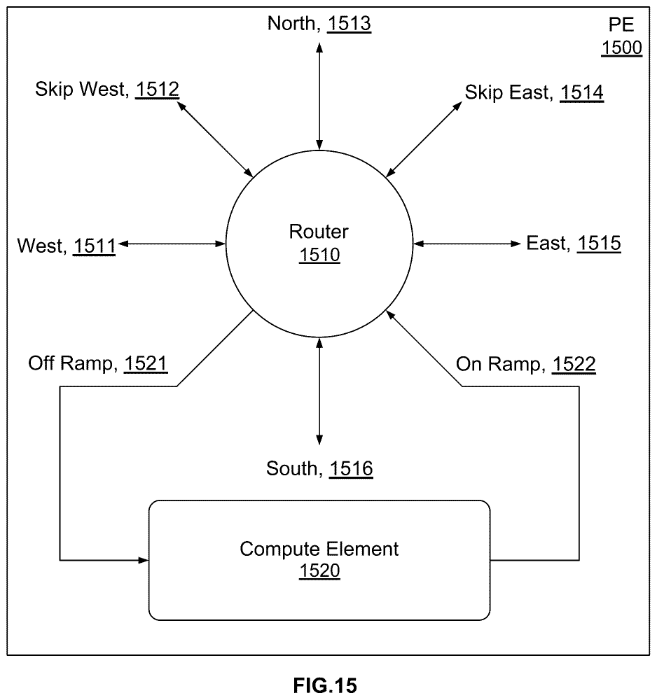

FIG. 15 shows a block diagram illustrating an example PE as PE 1500 of a compute accelerator. PE 1500 comprises Router 1510 and Compute Element 1520. Router 1510 selectively and/or conditionally communicates (e.g. transmits and receives) data packets between other PEs (e.g., logically adjacent and/or physically adjacent PEs) and PE 1500 via couplings 1511-1516. Couplings 1511-1516 are illustrated as bidirectional arrows to emphasize the bidirectional communication of data packets on the couplings. Backpressure information is also transmitted on the couplings in the reverse direction of packet information the backpressure corresponds to. Router 1510 selectively and/or conditionally communicates data packets to PE 1500 (e.g., Compute Element 1520) via Off Ramp 1521 and communicates data packets from PE 1500 (e.g., Compute Element 1520) via On Ramp 1522. Off Ramp 1521 is illustrated as a unidirectional arrow to emphasize the unidirectional communication of data packets on the coupling (e.g., from Router 1510 to Compute Element 1520). Backpressure information is also transmitted on the coupling in the reverse direction of packet information (e.g. from Compute Element 1520 to Router 1510). On Ramp 1522 is illustrated as a unidirectional arrow to emphasize the unidirectional communication of data packets on the coupling (e.g., from Compute Element 1520 to Router 1510). Backpressure information is also transmitted on the coupling in the reverse direction of packet information (e.g. from Router 1510 to Compute Element 1520).

Compute Element 1520 performs computations on data embodied in the data packets according to instruction address information derivable from the data packets. The instruction address information is used to identify starting addresses of tasks embodied as instructions stored in storage (e.g., any one or more of memory, cache, and register file(s)) of the compute element. Results of the computations are selectively and/or conditionally stored in the storage and/or provided as data embodied in data packets communicated to the router for, e.g., transmission to the other PEs and or PE 1500.

In addition to data, Router 1510 selectively and/or conditionally communicates (e.g. transmits and receives) backpressure information between the other PEs and PE 1500 via couplings 1511-1516. Router 1510 selectively and/or conditionally transmits backpressure information to PE 1500 via On Ramp 1522. Router 1510 receives backpressure information from PE 1500 via Off Ramp 1521. The backpressure information provided to the other PEs, as well as the backpressure information provided to PE 1500, is used by the other PEs and PE 1500 to stall transmitting data (e.g., packets) that would otherwise be lost due to insufficient queue space to store the data in Router 1510. The backpressure information received from the other PEs and PE 1500 is used respectively by Router 1510 to prevent transmitting data (e.g., packets) that would otherwise be lost due respectively to insufficient queue space in the routers of the other PEs and insufficient space in input queues of Compute Element 1520.

In various embodiments, any one or more of 1511-1516 are omitted.

In some embodiments and/or usage scenarios, PE 1500 is an embodiment of PE 1599 of any of DLAs 1500A-1500C, and/or elements of PE 1500 correspond to an implementation of PE 1599. In some embodiments and/or usage scenarios, North 1513, East 1515, South 1516, and West 1511 correspond respectively to North coupling 1530, East coupling 1531, South coupling 1532, and West coupling 1533 of any of DLAs 1500A-1500C.

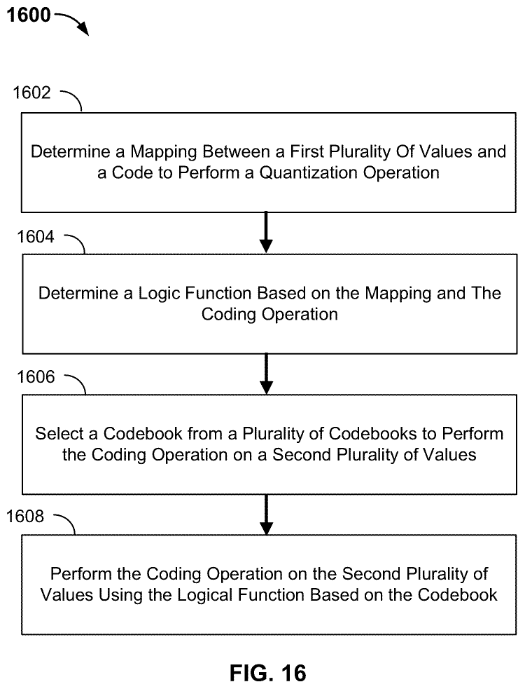

FIG. 16 is a flowchart of an example process 1600 for performing a coding operation, in accordance with one or more embodiments of the present disclosure. Process 1600 may be implemented at any suitable circuitry such as processing circuitry, an integrated circuit device, or circuitry configured as one or more PEs. For example, process 1600 may be implemented at any one or more of the following: CAU 1100, CAU 1200, DLA 1320, PEs 1322, DLA 1400A, DLA 1400B, DLA 1400C, ASIC 1410, PE cluster 1481, PE 1497, PE 1498, PE 1499, PE 1500, or any other suitable circuitry described herein. In some embodiments, process 1600 may be implemented in one device or distributed among multiple devices.

As an example, processing circuitry may perform one or more steps of process 1600 during a task (e.g., training, inference, or computations) and/or one or more steps of process 1600 offline. For example, steps 1606-1608 may be performed during inference, while steps 1602-1604 may occur offline (e.g., while the processing circuitry is not performing a task). It will be understood that processing circuitry may include circuitry at one or more servers and circuitry at one or more chips used to perform a task. For example, steps 1602-1604 may be performed at one or more servers across one or more devices. In another example, steps 1606-1608 may be performed at one or more chips (e.g., PE 1599), where such chips are also considered to be processing circuitry. It will be further understood that processing circuitry may be included as a component of any of the aforementioned components disclosed herein (e.g., any component or combination of components as previously described above in connection with FIGS. 13-15).

In some embodiments, at step 1602, processing circuitry may determine a mapping between a first plurality of values and a code to perform a quantization operation. In some embodiments, processing circuitry may determine a mapping by receiving a mapping or any type of suitable indication of a mapping. For example, a mapping may be received from circuitry that is external to processing circuitry. In some embodiments, processing circuitry may determine a mapping locally. For example, processing circuitry may, by itself, determine how to map between a first plurality of values and a code. In some embodiments, processing circuitry may determine suitable encodings and conversions between floating point and integer values prior to on-chip inference occurring (e.g., as previously discussed in connection with FIGS. 2-3). In some embodiments, processing circuitry performing step 1602 may be located on a single device. In some embodiments, processing circuitry performing step 1602 may include circuitry spread across multiple devices and/or multiple servers.

In some embodiments, a first plurality of values includes one or more weights of a neural network or any suitable artificial intelligence architecture. Each value of a first plurality of values may be of a first precision level (e.g., a full or native precision level). For example, each value of a first plurality of values may be in FP32, FP16, any other type of representation, or the like. In some embodiments, a code may be an index that is of a lower precision than a first plurality of values in a full precision level. For example, a code may be a 4-bit integer, and each value of a first plurality of values in a full precision level may be FP32 values. In some embodiments, a first plurality of values may be of a higher precision than a code representing a first plurality of values.

In some embodiments, mapping a first plurality of values to a code includes determining a reconstruction error from converting a first plurality of values between a native representation and a code. A reconstruction error may be indicative of a loss in precision when converting values from a higher representation to a lower representation. As such, processing circuitry may be configured to reduce a reconstruction error produced when mapping a first plurality of values to a code. For example, when mapping values to a code, processing circuitry may be configured to run an error reduction process (e.g., as previously described in connection with FIG. 5).

In some embodiments, at step 1604, processing circuitry may determine a logic function based on a mapping and a coding operation. Similar to step 1604, processing circuitry may determine a logic function by receiving a logic function or any suitable indication of a logic function from an external source. In some embodiments, processing circuitry may determine a logic function locally (e.g., processing circuitry may, by itself, determine a logic function). In some embodiments, processing circuitry may determine a logic function as previously discussed in FIG. 2, where processing circuitry may be configured to iteratively determine a logic function that is of simplest form and able to realize an encoding or a decoding. In some embodiments, processing circuitry performing step 1604 may be located on a single device. In some embodiments, processing circuitry performing step 1604 may include circuitry spread across multiple devices and/or multiple servers. It will be understood that processing circuitry that performs steps 1602 and 1604 may be the same processing circuitry that performs steps 1606 and 1608. For example, a device including processing circuitry may perform steps 1602-1604 prior to an inference task, and the same device may perform steps 1606-1608 during an inference task.

In some embodiments, a quantization operation includes a forward quantization operation, and a coding operation includes an encoding operation. A forward quantization operation may be any suitable operation that maps a higher precision value to a lower precision value. For example, a forward quantization operation may include mapping a value natively represented as an FP32 value to an INT4 value. An encoding operation may be any suitable operation that converts a value from a higher precision representation to a lower precision representation. For example, an encoding operation may include encoding each of values 204 to code 202.

In some embodiments, when performing an encoding operation, processing circuitry may be configured to round a second plurality of values and use the rounded plurality of values as input into a logic function. In some embodiments, when performing an encoding operation, processing circuitry may be configured to saturate a second plurality of values based on a maximum representable value and use the saturated second plurality of values as input into a logic function. Saturation may include clamping a value to a nearest maximum or minimum limit. For example, if original weights range from −10 to 10, but a quantized scale ranges from −1 to 1, then any weight greater than 1 may be saturated to 1 in the quantized scale. It will be understood that any other suitable type of modification (e.g., as previously described in connection with modification 308A) may be performed when performing an encoding operation.

In some embodiments, a quantization operation includes a de-quantization operation, and a coding operation includes a decoding operation. A de-quantization operation may be any suitable operation that reconstructs a higher precision value from a lower precision value. For example, a de-quantization operation may include determining an FP32 value based on an INT4 value. An FP32 value determined based on a de-quantization operation may be an approximation. A decoding operation may be any suitable operation that converts a value from a lower precision representation to a higher precision representation. For example, a decoding operation may include converting code 202 to at least one value of values 204.

It will be understood that encoding and quantization are similar processes. Additionally, it will be understood that decoding and de-quantization are similar processes. In some embodiments, encoding and decoding refer to downcasting and upcasting of data, respectively. In some embodiments, quantization and de-quantization refer to the mapping between values of the higher precision to lower precision and lower precision to higher precision, respectively.

In some embodiments, when determining a logic function based on a mapping and a coding operation, processing circuitry may be configured to reduce a complexity metric associated with performing the coding operation using the logic function. In some embodiments, a complexity metric is indicative of a number of operations of a logic function. As previously discussed above in connection with FIG. 5, a complexity metric may include a count of a sum of products form of a logic function. For example, processing circuitry may be configured to determine a complexity of a Boolean expression based on a number of implicants. In some embodiments, processing circuitry may be configured to determine a logic function based on a Boolean expression that is of simplest form (e.g., only includes prime implicants). Any suitable metric, loss function, or process may be applied to determine a logic function that may be used to efficiently perform encoding or decoding.

In some embodiments, at step 1606, processing circuitry may select a codebook from a plurality of codebooks to perform a coding operation on a second plurality of values. For example, as previously discussed in connection with FIG. 3 by signal 306, a codebook may be selected based on a distribution, statistic, or any suitable information regarding a second plurality of values. Different pluralities of values may have different distributions, so different codebooks may be better suited for certain distributions. In some embodiments, a second plurality of values may be a block of values (e.g., values 204). In some embodiments, a selected codebook is based on a first plurality of values. For example, a selected codebook may be determined based on signal 306. Furthermore, in some embodiments, each of a plurality of codebooks is tuned based on a respective numerical distribution. That is, multiple codebooks may be generated, and each codebook may be suitable for different types of numerical distributions. For example, a first codebook of a plurality of codebooks may be suitable for distributions where a maximum exponent is 10 and a second codebook of a plurality of codebooks may be suitable for distributions where a maximum exponent is 20. In some embodiments, different codebooks may be tuned for different distributions based on achieving different reconstruction errors. For example, a first codebook may achieve a more desirable reconstruction error when used for values having a first distribution compared to values having a second distribution. Meanwhile, a second codebook may achieve a more desirable reconstruction error when used for values having a second distribution compared to values having a first distribution.

In some embodiments, a second plurality of values and a first plurality of values share a characteristic. In some embodiments, a characteristic includes at least one of: a maximum exponent, a distribution metric, or a statistic. For example, as previously discussed above in connection with FIG. 4, different pluralities of values may share a characteristic, such as having the same number of values with a maximum exponent. In another example, different pluralities of values may share a characteristic, such as having the same number of positive values or the same number of negative values.

In some embodiments, at step 1608, processing circuitry may perform a coding operation on a second plurality of values using a logical function based on a codebook. For example, processing circuitry may perform a decoding operation to determine values 204 from code 202 (e.g., as previously discussed in connection with FIGS. 2-3). In another example, as previously discussed in connection with FIGS. 7-9, processing circuitry may perform an encoding or decoding operation based on a respective logic function. As previously discussed in connection with FIGS. 2-3, to decode code 202 to values 204, processing circuitry may use decoding unit 206. Similarly, to encode values 204 to code 202, unit 210 may be used.

In some embodiments, a particular data format may be used (e.g., in applications where outliers may be significant to performance, accuracy, or any other suitable metric). In some embodiments, processing circuitry may be configured to determining an outlier of a second plurality of values and determine, for each of a second plurality of values, a respective offset based on an outlier, where a respective offset of an outlier is encoded as a center of a second plurality of values. As previously discussed above in connection with FIG. 6, a plurality of values may be stored such that each value shares a common maximum value, where the common value is stored in native precision.

In some embodiments, control circuitry may be configured to generate a codebook and optimize a codebook. In some embodiments, a codebook may be optimized based on reducing a reconstruction error of a target distribution (e.g., as previously discussed above in connection with FIG. 5). In some embodiments, a codebook may be optimized based on a complexity metric of one or more logic functions (e.g., as previously discussed above in connection with FIG. 5).

In some embodiments, control circuitry may be configured to reduce a reconstruction error and reduce a complexity metric. In some embodiments, reduction of a construction error and a complexity metric may occur independently or concurrently. As previously discussed above in connection FIG. 5, at least one of an error reduction process or a logic complexity reduction process may be used to reduce a reconstruction error or complexity metric, respectively.

In some embodiments, a logic function may be configured to convert a code to at least one numerical value based on mappings of a codebook. For example, any one of logic units 302A-302N may be used to convert code 202 to values 204, and any one of logic units 310A-310N may be used to convert values 204 to code 202.

In some embodiments, when converting values to a code based on a codebook, a rounding, saturation, or any suitable modification operation may occur. For example, any one or more of modifications 308A-308N may be applied to values 204. After modifications are applied to values 204, such modified values may be used as input for any one of units 310A-310N.

In some embodiments, processing circuitry may receive a selection signal (e.g., signal 306). In some embodiments, processing circuitry may select a codebook from a plurality of codebooks. Each codebook of a plurality of codebooks may be optimized based on reducing reconstruction error and/or a complexity metric. In some embodiments, a selection signal may be based on a statistical analysis of values to be encoded. For example, processing circuitry may perform a statistical analysis on values 204 to determine a characteristic (e.g., a maximum exponent).

In some embodiments, processing circuitry may be configured to determine one or more parameters of a codebook based on reducing a reconstruction error and complexity metric (e.g., where such a reduction may occur simultaneously or independently). In some embodiments, processing circuitry may be configured to generate a codebook based on one or more determined parameters.

In some embodiments, a data structure may represent a numerical value. A data structure may include a plurality of blocks (e.g., where a block may be any suitable group of numerical values), where each block is associated with a shared maximum value and offsets based on a shared maximum value. A data structure may include one or more sign buts, where each sign bit indicates an agreement or opposition based on a sign of a shared maximum value. For example, as previously described above in connection with FIG. 6, a block may share a common maximum value (e.g., value 602). Values of the same block may be represented as offsets from a common maximum value (e.g. value 604). In some embodiments, an outlier of a block may be the same as a maximum of a block of values. In some embodiments, an outlier may serve as a center of a block of values. A center of a block of values may function similarly to a centroid in a K-means cluster.

In some embodiments, a component may be configured to convert numerical values into to a block numeric format based on a data structure as previously described above (e.g., in connection with FIG. 6).

In some embodiments, a component may be configured to interpret data organized in a block numeric format represented by a data structure and reconstruct a numerical value based on interpreted data.

In some embodiments, a data structure may represent a block numeric format. A data structure may include a shared maximum for each block of a plurality of blocks and a shared codebook. A data structure may further include a plurality of value offsets based on a shared maximum, where a value offset may be represented by codes of a selected codebook.

In some embodiments, one or more components may be configured to convert numerical values to a block format represented by a data structure. In some embodiments, one or more components may be configured to encode offsets as codes.

In some embodiments, one or more components may be configured to reconstruct numerical values of a block numeric format represented by a data stricture, where one or more components are configured to interpret codes and determine offsets based on codes.

In some embodiments, an accelerator (e.g., CAU 1100 or 1200) may include at least one input decoding unit. In some embodiments, an input decoding unit may be configured to process data by reconstructing numerical values from a block numeric format represented by a data structure as previously discussed in FIG. 6. In some embodiments, at least one input decoding unit may be configured to interpret codes and determine offsets based on codes. In some embodiments, an accelerator may further include at least one output encoding unit to process data by converting numerical values to a block numeric format represented by a data structure as previously discussed in FIG. 6. In some embodiments, at least one output encoding unit may be configured to encode offsets as codes.

In some embodiments, an accelerator may include a local memory store (e.g., local memory store 1202), where at least one input decoding unit and/or at least one output encoding unit are configured to process data transfers with a local memory store.

Any parameters described in the present disclosure may include any combination of scalars, vectors, matrices, tensors, and so forth, such as arrangements of an arbitrary number and an arbitrary complexity of elements. For example, the parameters are of various dimensions, such as one-dimensional, two-dimensional, three-dimensional, and otherwise multidimensional. For example, the parameters are of various datatypes, such as, integer and floating-point. For example, the parameters (or respective portions thereof, e.g., an exponent or a mantissa) are represented with various precisions (sometimes referred to as widths), such as, 8-bit, 16-bit, 32-bit, 64-bit, and so forth.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

An enumerated listing of items does not imply that any or all of the items are mutually exclusive, unless expressly specified otherwise.

The terms “a”, “an” and “the” mean “one or more”, unless expressly specified otherwise.

Devices, or components thereof, that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least particular operations that may have been illustrated in the figures show particular events occurring in a particular order. In some alternative embodiments, particular operations may be performed in a different order, modified, combined, or removed. Moreover, steps may be added to the above-described circuitry(ies) and conform to the described embodiments without departing from the principles set forth in the present disclosure. Some operations described herein may occur sequentially, and/or particular operations may be processed in parallel. Any operation may be performed by a single processor or by distributed processors.

The processes discussed above are intended to be illustrative and not limiting. One skilled in the art would appreciate that the steps of the processes discussed herein may be omitted, modified, combined and/or rearranged, and any additional steps may be performed without departing from the scope of the invention.

The foregoing is merely illustrative of the principles of this disclosure, and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations thereto and modifications thereof, which are within the spirit of the following claims.

What is claimed is:

1. A method for performing a coding operation, the method comprising:
determining a mapping between a first plurality of values and a code to perform a quantization operation;
determining a logic function based on the mapping and the coding operation;
selecting a codebook from a plurality of codebooks to perform the coding operation on a second plurality of values, wherein:
the selected codebook is based on the first plurality of values; and
the second plurality of values and the first plurality of values share a characteristic; and
performing the coding operation on the second plurality of values using the logic function based on the codebook.

2. The method of claim 1, wherein the quantization operation comprises a forward quantization operation and the coding operation comprises an encoding operation.

3. The method of claim 2, further comprising:
rounding the second plurality of values; and
using the rounded plurality of values as input into the logic function.

4. The method of claim 2, further comprising:
saturating the second plurality of values based on a maximum representable value; and
using the saturated second plurality of values as input into the logic function.

5. The method of claim 1, wherein the quantization operation comprises a de-quantization operation and the coding operation comprises a decoding operation.

6. The method of claim 1, wherein determining the mapping between the first plurality of values and the code comprises determining a reconstruction error from converting the first plurality of values between a native representation and the code.

7. The method of claim 1, wherein:
determining the logic function based on the mapping and the coding operation comprises reducing a complexity metric associated with performing the coding operation using the logic function; and
the complexity metric is indicative of a number of operations of the logic function.

8. The method of claim 1, wherein the characteristic comprises at least one of: a maximum exponent, a distribution metric, or a statistic.

9. The method of claim 1, wherein each of the plurality of codebooks is tuned based on a respective numerical distribution.

10. The method of claim 1, further comprising:
determining an outlier of the second plurality of values; and
determining, for each of the second plurality of values, a respective offset based on the outlier, wherein the respective offset of the outlier is encoded as a center of the second plurality of values.

11. A system configured to perform a coding operation, the system comprising circuitry configured as a plurality of processing elements (PEs), wherein the circuitry is configured to:
determine a mapping between a first plurality of values and a code to perform a quantization operation;
determine a logic function based on the mapping and the coding operation;
select a codebook from a plurality of codebooks to perform the coding operation on a second plurality of values, wherein:
the selected codebook is based on the first plurality of values; and
the second plurality of values and the first plurality of values share a characteristic; and
perform the coding operation on the second plurality of values using the logic function based on the codebook.

12. The system of claim 11, wherein the quantization operation comprises a forward quantization operation and the coding operation comprises an encoding operation.

13. The system of claim 12, wherein the circuitry is further configured to:
round the second plurality of values; and
use the rounded plurality of values as input into the logic function.

14. The system of claim 12, wherein the circuitry is further configured to:
saturate the second plurality of values based on a maximum representable value; and
use the saturated second plurality of values as input into the logic function.

15. The system of claim 11, wherein the quantization operation comprises a de-quantization operation and the coding operation comprises a decoding operation.

16. The system of claim 11, wherein the circuitry, when determining the mapping between the first plurality of values and the code, is configured to determine a reconstruction error from converting the first plurality of values between a native representation and the code.

17. The system of claim 11, wherein:
the circuitry, when determining the logic function based on the mapping and the coding operation, is configured to reducing a complexity metric associated with performing the coding operation using the logic function; and
the complexity metric is indicative of a number of operations of the logic function.

18. The system of claim 11, wherein the characteristic comprises at least one of: a maximum exponent, a distribution metric, or a statistic.

19. The system of claim 11, wherein each of the plurality of codebooks is tuned based on a respective numerical distribution.

20. The system of claim 11, wherein the circuitry is further configured to:
determine an outlier of the second plurality of values; and
determine, for each of the second plurality of values, a respective offset based on the outlier, wherein the respective offset of the outlier is encoded as a center of the second plurality of values.
